(19) United States
(12) Patent Application Publication
(10) Pub. No.: US 2026/0188256 A1
(43) Pub. Date: Jul. 2, 2026

(54) DISPLAY PANEL AND DISPLAY APPARATUS

(71) Applicant: Xiamen Tianma Optoelectronics Co., Ltd., Xiamen (CN)

(72) Inventors: Jiaqi YUE, Xiamen (CN); Zongcai Ding, Xiamen (CN); Weiqiang Wu, Xiamen (CN); Jie Lin, Xiamen (CN); Rianci Li, Xiamen (CN); Xiaohe Li, Xiamen (CN); Jinquan Liu, Xiamen (CN); Xuhui Peng, Xiamen (CN)

(73) Assignee: Xiamen Tianma Optoelectronics Co., Ltd., Xiamen (CN)

(21) Appl. No.: 19/435,693

(22) Filed: Dec. 29, 2025

(30) Foreign Application Priority Data
Dec. 30, 2024 (CN) 202411974730.1

(51) Int. Cl. G09G 3/3266; G09G 3/32; G09G 3/3233; G09G 3/36; G11C 19/28

(52) U.S. Cl. CPC G09G 3/3266; G09G 3/3233; G11C 19/287; G09G 3/32; G09G 3/3677; G09G 2300/0421; G09G 2300/0842; G09G 2300/0861; G09G 2310/0286; G09G 2310/08; G09G 2320/0223

(57) ABSTRACT

Embodiments of the present application provide a display panel and a display apparatus. An output terminal of an enable output module of a shift register in a first scan drive circuit is electrically connected to a first end of a first scan wire, an input terminal of a compensation module in a first compensation module group is electrically connected to a first non-enable signal wire, and an output terminal of the compensation module in the first compensation module group is electrically connected to a second end of the first scan wire; in the shift register and the compensation module electrically connected to the same first scan wire, the compensation module is turned on in a switching period in which the enable output module in the shift register switches from outputting an enable signal to outputting a non-enable signal.

### CROSS-REFERENCE TO RELATED APPLICATIONS

This application claims priority to Chinese Patent Application No. 202411974730.1, titled “DISPLAY PANEL AND DISPLAY APPARATUS” and filed on Dec. 30, 2024, which is hereby incorporated by reference in its entirety.

### TECHNICAL FIELD

The present application relates to the technical field of display, and particularly, relates to a display panel and a display apparatus.

### BACKGROUND

With the development of display technologies, users generally prefer display apparatuses with high screen-to-body ratio, so that narrow bezel display has become an important research direction in the field of display technology. In the display panel of the display apparatus, the reduction of the width of the bezel region is limited by the scan drive circuit to a great extent. In order to achieve the narrow bezel, single-side driving is used in a scan wire in the display panel, that is, one end of the scan wire is electrically connected to the shift register, and the other end is not electrically connected to the shift register. However, the single-side driving may cause the problem of poor display uniformity of the display panel.

### SUMMARY

In view of this, embodiments of the present application provide a display panel and a display apparatus to solve the above problems.

In a first aspect, embodiments of the present application provide a display panel including a first scan wire, a first scan drive circuit, and a first compensation module group. The first scan drive circuit includes a plurality of stages of shift registers in a cascaded connection, the shift registers each includes an enable output module, and an output terminal of the enable output module of the shift register in the first scan drive circuit is electrically connected to a first end of the first scan wire; and the first compensation module group includes a plurality of compensation modules, an input terminal of the compensation module is electrically connected to a first non-enable signal wire, and an output terminal of the compensation module is electrically connected to a second end of the first scan wire; where in the shift register in the first scan drive circuit and the compensation module in the first compensation module group electrically connected to the same first scan wire, the compensation module is turned on in a switching period of the shift register; and the switching period is a period in which the enable output module switches from outputting an enable signal to outputting a non-enable signal.

In a second aspect, an embodiment of the present application provides a display apparatus including the display panel according to the first aspect.

### BRIEF DESCRIPTION OF THE DRAWINGS

In order to illustrate the technical solutions of the embodiments of the present application more clearly, the drawings to be used in the embodiments will be briefly introduced below, apparently, the drawings described below are merely some embodiments of the present application, and for those skilled in the art, other drawings can be obtained based on these drawings without inventive effort.

FIG. 1 is a partial schematic view of a display panel according to an embodiment of the present application;

FIG. 2 is a partial schematic view of a display panel according to an embodiment of the present application;

FIG. 3 is a schematic view of a display panel according to an embodiment of the present application;

FIG. 4 is a schematic view of a connection of a shift register and a compensation module to a first scan wire according to an embodiment of the present application;

FIG. 5 is an operation time sequence diagram corresponding to FIG. 4;

FIG. 6 is a schematic view of a pixel circuit according to an embodiment of the present application;

FIG. 7 is an existing operation time sequence diagram corresponding to the pixel circuit shown in FIG. 6;

FIG. 8 is an operation time sequence diagram corresponding to the pixel circuit shown in FIG. 6;

FIG. 9 is an equivalent circuit diagram of the pixel circuit corresponding to FIG. 6;

FIG. 10 is a schematic view of a connection of a shift register and a compensation module to a first scan wire according to an embodiment of the present application;

FIG. 11 is an operation time sequence diagram corresponding to FIG. 10;

FIG. 12 is another operation time sequence diagram corresponding to FIG. 10;

FIG. 13 is an equivalent circuit diagram of a compensation module according to an embodiment of the present application;

FIG. 14 is an equivalent circuit diagram of a shift register and a compensation module according to an embodiment of the present application;

FIG. 15 is an operation time sequence diagram corresponding to FIG. 14;

FIG. 16 is a schematic view of a display panel according to an embodiment of the present application;

FIG. 17 is a schematic view of a display panel according to an embodiment of the present application;

FIG. 18 is a schematic view of a display panel according to an embodiment of the present application;

FIG. 19 is a schematic view of a display panel according to an embodiment of the present application;

FIG. 20 is an operation time sequence diagram corresponding to FIG. 19;

FIG. 21 is a partial schematic view of a display panel according to an embodiment of the present application;

FIG. 22 is a partial schematic view of a display panel according to an embodiment of the present application;

FIG. 23 is a schematic view of a display panel according to an embodiment of the present application;

FIG. 24 is a partial schematic view of a display panel according to an embodiment of the present application;

FIG. 25 is a partial schematic view of a display panel according to an embodiment of the present application;

FIG. 26 is a partial schematic view of a display panel according to an embodiment of the present application;

FIG. 27 is a partial schematic view of a display panel according to an embodiment of the present application;

FIG. 28 is a schematic view of a display panel according to an embodiment of the present application;

FIG. 29 is a schematic structural view of different transistors in a display panel according to an embodiment of the present application; and

FIG. 30 is a schematic view of a display apparatus according to an embodiment of the present application.

### DETAILED DESCRIPTION

In order to better understand the technical solution of the present application, embodiments of the present application will be described in detail below with reference to the drawings.

It should be clear that the described embodiments are only some but not all of the embodiments of the present application. Based on the embodiments of the present application, all other embodiments obtained by those skilled in the art without any creative work fall within the protection scope of the present application.

The terms used in the embodiments of the present application are for the purpose of describing particular embodiments only and are not intended to limit the present application. Unless the context clearly indicates, the singular forms “a” and “the” used in the embodiments and the appended claims of the present application are also intended to include plural forms.

It should be understood the term “and/or” used herein refers to only an association relationship for describing associated objects, and means that there may be three types of relationships. For example, “A and/or B” may represent three cases include that: “A exists alone”, “A and B exist simultaneously”, and “B exists alone”. In addition, the character “/” herein generally indicates that the associated objects have an “or” relationship.

In the description of this specification, it should be understood that expressions such as “basically”, “approximately”, “roughly”, “about”, “around” and “substantially” described in the claims and embodiments of this application mean that a value is a generally agreed rather than an exact value within a reasonable process operation range or within a tolerance range.

It should be understood that, although the terms such as first and second may be used for describing the transistors and the like in embodiments of the present application, these should not be limited to these terms. These terms are only used for distinguishing the transistors and the like from each other. For example, without departing from the scope of the embodiments of the present application, the first transistor may be referred to as the second transistor, and similarly, the second transistor may be referred to as the first transistor. Through detailed and deep research, the applicants of the present application provide a solution for the problems existing in the related art.

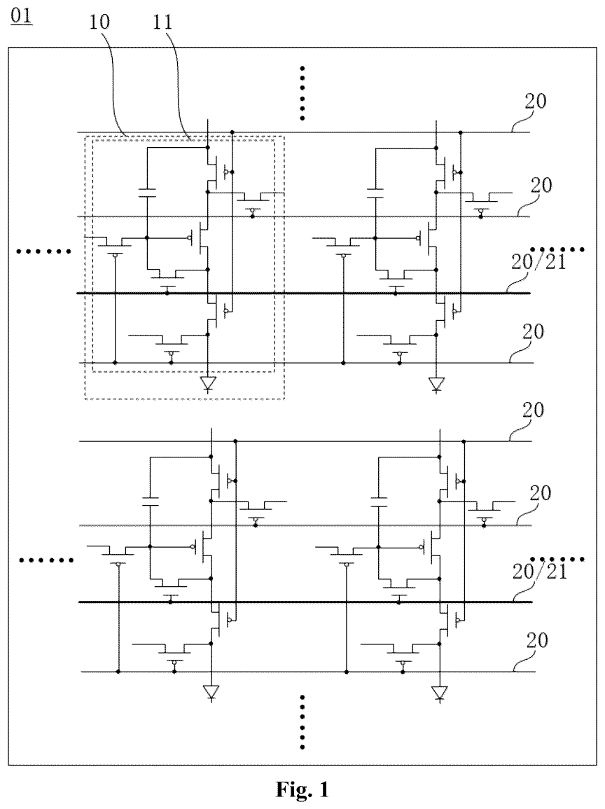

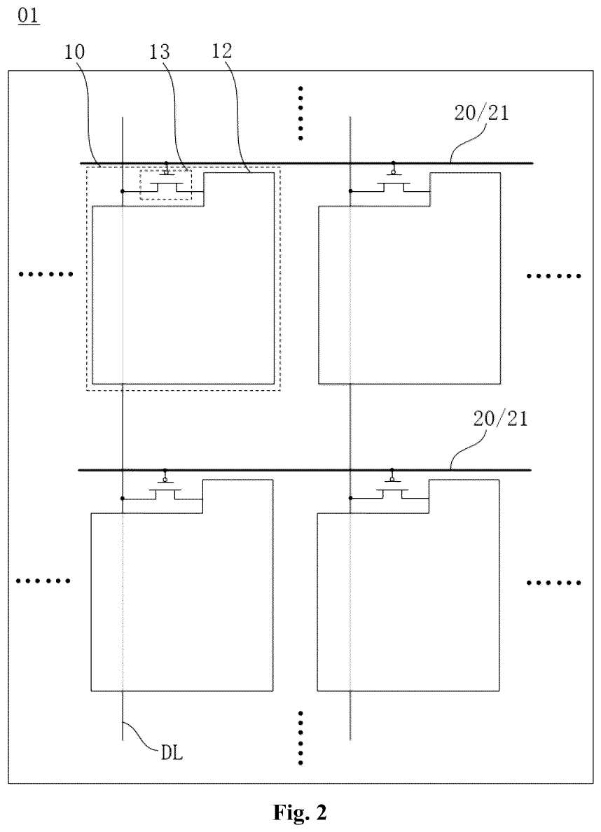

FIG. 1 is a partial schematic view of a display panel according to an embodiment of the present application, and FIG. 2 is a partial schematic view of a display panel according to an embodiment of the present application.

As shown in FIG. 1 and FIG. 2, the display panel 01 includes a plurality of pixels 10 and a plurality of scan wires 20. As shown in FIG. 1, the pixel 10 may include the pixel circuit 11, and the scan wire 20 is electrically connected to the same row of pixel circuits 11 to drive the pixel circuits 11 to operate row by row. As shown in FIG. 2, the pixel 10 may further include the pixel electrode 12 and the pixel switch 13 electrically connected to the pixel electrode 12, and the scan wire 20 is electrically connected to the same row of pixel switches 13 to drive the pixel switches 13 to operate row by row. The inventive concept of the present application can be applied to the display panel 01 including the pixel circuits 11 shown in FIG. 1 or the display panel 01 including the pixel electrodes 12 and the pixel switches 13 shown in FIG. 2. The display panel 01 shown in FIG. 1 may be an organic light-emitting diode (OLED) display panel, a Micro-LED display panel, a Mini-LED display panel, or the like; and the display panel 01 shown in FIG. 2 may be a liquid crystal display panel (LCD), or the like.

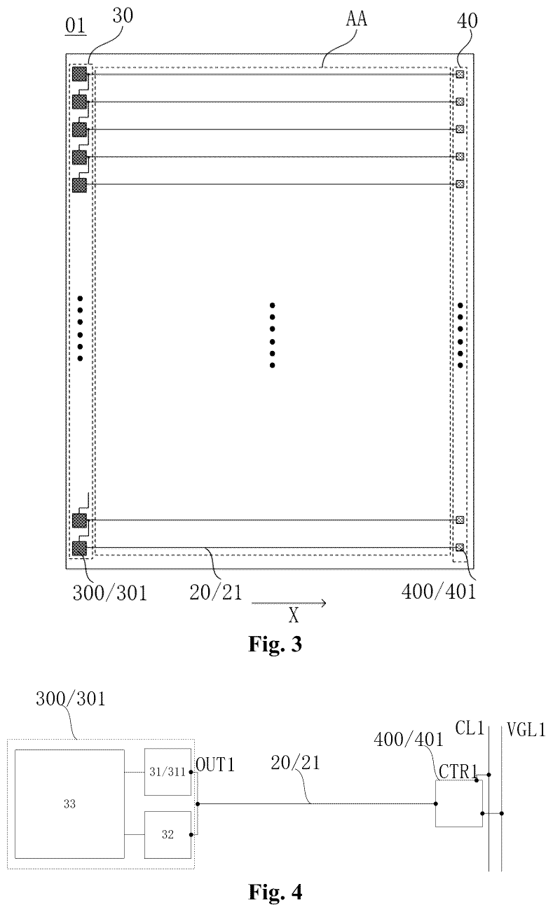

FIG. 3 is a schematic view of a display panel according to an embodiment of the present application.

Referring to FIG. 3, FIG. 1 and FIG. 2, the display panel 01 includes the first scan drive circuit 30 and the first compensation module group 40. The first scan drive circuit 30 includes a plurality of stages of shift registers 300 in a cascaded connection, and the output terminals of the plurality of stages of shift registers 300 in the first scan drive circuit 30 are electrically connected to different first scan wires 21, respectively; the first compensation module group 40 includes a plurality of compensation modules 400, and the output terminals of the plurality of compensation modules 400 in the first compensation module group 40 are electrically connected to different first scan wires 21, respectively.

For the sake of clarity, only a part of the structures in the display panel 01 are shown in FIG. 3; and in a real product, the structures in the display panel 01 are not limited to the structures shown in FIG. 3.

Still referring to FIG. 3, the output terminals of the shift registers 300 in the first scan drive circuit 30 are electrically connected to the first ends of the first scan wires 21, and the output terminals of the compensation modules 400 in the first compensation module group 40 are electrically connected to the second ends of the first scan wires 21. At least a part of the first scan wires 21 are electrically connected to the shift registers 300 in the first scan drive circuit 30 and the compensation modules 400 in the first compensation module group 40 at the same time; that is, the first ends of at least a part of the first scan wires 21 are electrically connected to the shift registers 300 in the first scan drive circuit 30, and the second ends of at least a part of the first scan wires 21 are electrically connected to the compensation modules 400 in the first compensation module group 40; for example, the first scan wires 21 are all electrically connected to the shift registers 300 in the first scan drive circuit 30 and the compensation modules 400 in the first compensation module group 40 at the same time.

The first scan wires 21 may be the same type of scan wires 20 of the plurality of scan wires 20 in the display panel 01. For example, referring to FIG. 1, under a condition that the display panel 01 includes the pixel circuits 11 and the pixel circuits 11 each include a plurality of transistors, the transistors electrically connected to different first scan wires 21 are the transistors having the same function in the pixel circuits 11. For example, referring to FIG. 2, under a condition that the display panel 01 includes the switching transistors connected between the pixel electrodes 12 and the data wire DL, the transistors electrically connected to different first scan wires 21 may all be the switching transistors.

FIG. 4 is a schematic view of a connection of a shift register and a compensation module to a first scan wire according to an embodiment of the present application.

As shown in FIG. 4, the shift register 300 includes the enable output module 31, the enable output module 31 is configured to output at least the enable signal to the scan wire 20 electrically connected to the enable output module 31, and the enable signal output by the enable output module 31 can control the transistor electrically connected to the scan wire 20 to be turned on. The output terminal of the enable output module 31 of the shift register 300 in the first scan drive circuit 30 is electrically connected to the first end of the first scan wire 21, and the output terminal of the enable output module 31 may be the output terminal of the shift register 300. Unless otherwise specified, the example in which the enable signal output by the shift register 300 of the first scan drive circuit 30 is at the high level is taken below for illustration.

For convenience of description, the shift register 300 in the first scan drive circuit 30 is referred to as the first shift register 301, and the enable output module 31 in the shift register 300 of the first scan drive circuit 30 is referred to as the first enable output module 311. The first enable output module 311 in this embodiment is configured to output at least the enable signal to the first scan wire 21, so that the first scan wire 21 can control the transistor electrically connected to the first scan wire 21 to be turned on when transmitting the enable signal.

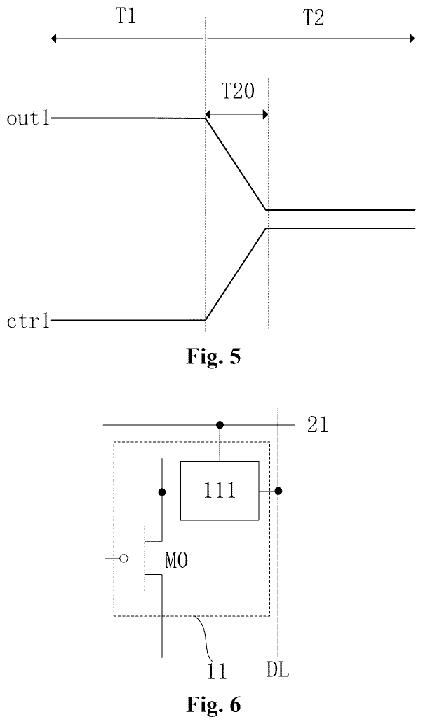

FIG. 5 is an operation time sequence diagram corresponding to FIG. 4.

Referring to FIG. 5, the operation process of the shift register 300 may include the enable stage T1 and the non-enable stage T2, and the enable output module 31 of the shift register 300 outputs the enable signal in the enable stage T1. Then, as shown in FIG. 5, the output terminal OUT1 of the first enable output module 311 transmits the enable signal to the first scan wire 21 by the first end of the first scan wire 21 in the enable stage T1 of the shift register 300 to which the output terminal OUT1 of the first enable output module 311 belongs. Referring to FIG. 5 and FIG. 4, out1 represents the signal of the output terminal OUT1 of the first enable output module 311, and out1 represents the high level of the enable signal in the enable stage T1.

Under a condition that the first enable output module 311 finishes outputting the enable signal, it means that the enable stage T1 of the first shift register 301 to which the first enable output module 311 belongs ends. Under this condition, if the first enable output module 311 is immediately turned off, the charge on the first scan wire 21 electrically connected to the first enable output module 311 cannot be effectively discharged, so that the transistor electrically connected to the first scan wire 21 cannot be effectively turned off, and the transistor may be mischarged with the signal.

Therefore, after the first enable output module 311 of the first shift register 301 finishes outputting the enable signal, the first enable output module 311 is not immediately turned off but remains to be turned on, so that the charge on the first scan wire 21 is discharged. Under this condition, the first enable output module 311 switches from outputting the enable signal to outputting the non-enable signal, so that the first scan wire 21 can transmit the correct signal in the non-enable stage T2 after the enable stage T1 of the shift register 300 ends, so as to accurately control the ON state and the OFF state of the transistor electrically connected to the first scan wire 21. That is, as shown in FIG. 5, the initial period in which the first shift register 301 finishes the enable stage T1 and enters the non-enable stage T2 is the switching period T20, and the switching period T20 is a period in which the enable output module 31 switches from outputting the enable signal to outputting the non-enable signal; that is, the first enable output module 311 switches from outputting the enable signal to outputting the non-enable signal in the initial period in which the first shift register 301 finishes the enable stage T1 and enters the non-enable stage T2. For example, as shown in FIG. 5, out1 finally outputs the low level representing the non-enable signal in the non-enabled stage T2, and out1 switches from the high level to the low level in the switching period T20 of the non-enabled stage T2. Further, the first shift register 301 electrically connected to the first scan wire 21 switches from outputting the enable signal to outputting the non-enable signal in the switching period T20, so that the signal on the first scan wire 21 does not immediately switch from transmitting the enable signal to transmitting the non-enable signal, and correspondingly, in the switching period T20 of the first shift register 301, the transistor electrically connected to the first scan wire 21 switches from the ON state to the OFF state and is not immediately turned off.

As shown in FIG. 4, the input terminal of the compensation module 400 in the first compensation module group 40 is electrically connected to the first non-enable signal wire VGL1, the output terminal of the compensation module 400 of the first compensation module group 40 is electrically connected to the second end of the first scan wire 21, and the first non-enable signal wire VGL1 is configured for transmitting the non-enable signal. Unless otherwise specified, the example in which the enable signal is at the high level and the non-enable signal is at the low level is given below for illustration.

It should be noted that, in the real product, under a condition that the transistor electrically connected to and controlled by the first scan wire 21 is the N-channel transistor, the enable signal is at the high level, and the non-enable signal is at the low level; in the real product, under a condition that the transistor electrically connected to and controlled by the first scan wire 21 is the P-channel transistor, the enable signal is at the low level, and the non-enable signal is at the high level.

For convenience of description, the compensation module 400 in the first compensation module group 40 is referred to as the first compensation module 401. Under a condition that the first compensation module 401 is turned on, the first compensation module 401 may be configured to transmit the non-enable signal transmitted on the first non-enable signal wire VGL1 to the first scan wire 21 electrically connected to the first compensation module 401 by the second end of the first scan wire 21. Referring to FIG. 5 and FIG. 4, the potential signal of the control end CTR1 of the first compensation module 401 is represented by ctr1; unless otherwise specified, the example in which the first compensation module 401 is turned on under a condition that ctr1 is at the high level is given below for illustration. It should be noted that, in the real product, the first compensation module 401 may be turned on under a condition that ctr1 is at the low level.

In the embodiments of the present application, in the shift register 300 in the first scan drive circuit 30 and the compensation module 400 in the first compensation module group 40 electrically connected to the same first scan wire 21, the compensation module 400 is turned on in the switching period T20 of the shift register 300. Referring to FIG. 5 and FIG. 4, under a condition that the first shift register 301 electrically connected to the first scan wire 21 finishes the enable stage T1 and enters the switching period T20 of the non-enable stage T2, the first compensation module 401 electrically connected to the first scan wire 21 is turned on, that is, in the process in which the potential of the first end of the first scan wire 21 switches from the potential corresponding to the enable signal to the potential corresponding to the non-enable signal, the potential of the second end of the first scan wire 21 switches from the potential corresponding to the enable signal to the potential corresponding to the non-enable signal.

In the related art, under a condition that one end (referred to as the near end) of the scan wire 20 is electrically connected to the shift register 300 and the other end (referred to as the far end) is suspended, the near end of the scan wire 20 obtains the signal from the shift register 300, and there is the problem of voltage drop and delay under a condition that the signal is transmitted in the scan wire 20. Under a condition that the shift register 300 switches from outputting the enable signal to outputting the non-enable signal, the potential of the non-enable signal received by the far end of the scan wire 20 is different from the potential of the non-enable signal received by the near end of the scan wire 20 to a certain extent, and the far end of the scan wire 20 receives the non-enable signal later than the near end of the scan wire 20 does.

In the embodiments of the present application, the first end (the corresponding near end) of the first scan wire 21 is electrically connected to the shift register 300, and the second end (the corresponding far end) is electrically connected to the compensation module 400; under a condition that the shift register 300 outputs the non-enable signal to the first end of the first scan wire 21, the compensation module 400 outputs the non-enable signal to the second end of the first scan wire 21, and the first end and the second end of the first scan wire 21 both can receive the non-enable signal in close proximity, which effectively reduces the problem that the non-enable signals received by the first end and the second end of the first scan wire 21 are different from each other due to the voltage drop and the problem that the non-enable signal received by the second end of the first scan wire 21 is delayed.

Further, under a condition that one end (referred to as the near end) of the scan wire 20 is electrically connected to the shift register 300, and the other end (referred to as the far end) is suspended, in the transistors electrically connected to the scan wire 20, the moment at which the transistor in the vicinity of the far end is turned off is not as timely as the moment at which the transistor in the vicinity of the near end is turned off. On the one hand, the delay in transmission of the non-enable signal on the scan wire 20 causes the start moment at which the transistor in the vicinity of the far end is turned off to be later than the start moment at which the transistor in the vicinity of the near end is turned off; on the other hand, the voltage drop when the non-enable signal is transmitted on the scan wire 20 causes the time length in which the transistor in the vicinity of the far end is turned off to be greater than the time length in which the transistor in the vicinity of the near end is turned off. However, not turning off the transistor in time may cause the transistor to write the incorrect signal to the node electrically connected to the output terminal of the transistor, resulting in the abnormal display.

In view of this problem, the embodiments of the present application provide the corresponding solution, that is, in the shift register 300 in the first scan drive circuit 30 and the compensation module 400 in the first compensation module group 40 electrically connected to the same first scan wire 21, the compensation module 400 is turned on in the switching period T20 of the shift register 300; that is, in the process in which the potential of the first end of the first scan wire 21 switches from the potential corresponding to the enable signal to the potential corresponding to the non-enable signal, the potential of the second end of the first scan wire 21 switches from the potential corresponding to the enable signal to the potential corresponding to the non-enable signal. Therefore, the time length in which the transistor electrically connected to the vicinity of the first end of the first scan wire 21 is turned off is approximately equal to the time length in which the transistor electrically connected to the vicinity of the second end of the first scan wire 21 is turned off, and the moment at which the transistor electrically connected to the vicinity of the first end of the first scan wire 21 is turned off is almost the same as the moment at which the transistor electrically connected to the vicinity of the second end of the first scan wire 21 is turned off. With the technical solution according to the embodiments of the present application, the transistors electrically connected to different locations of the first scan wire 21 may all be turned off in time, which can effectively alleviate the problem of display abnormality.

It should be noted that, in the embodiments of the present application, the first scan drive circuit 30, the shift register 300 in the first scan drive circuit 30, and the enable output module 31 in the shift register 300, the first compensation module group 40, the compensation module 400 in the first compensation module group 40, and the first scan wire 21 are taken as the example to illustrate the inventive concept of the present application.

Further, the display panel 01 may further include the second scan drive circuit, the third scan drive circuit, and other scan drive circuits other than the first scan drive circuit 30, and the second scan drive circuit, the third scan drive circuit, and the like may each include the shift register 300, and the shift register 300 may include the enable output module 31; the display panel 01 may further include the second compensation module group, the third compensation module group, and other compensation module groups other than the first compensation module group 40, and the second compensation module group, the third compensation module group, and the like may each include the compensation module 400; and the display panel 01 may include the second scan wire, the third scan wire, and other scan wires 20 other than the first scan wire 21. The inventive concept of the present application may be applied to other scan drive circuits other than the first scan drive circuit 30, other compensation modules in the first compensation module group 40, and other scan wires 20 other than the first scan wire 21, which is not limited by the present application.

As shown in FIG. 4, the shift register 300 may further include the non-enable output module 32 and the control module 33, the non-enable output module 32 is configured to output the non-enable signal to the scan wire 20 electrically connected to the non-enable output module 32, and the non-enable signal output by the non-enable output module 32 can control the transistor electrically connected to the scan wire 20 to be turned off by the scan wire 20. The control module 33 is configured to control the enable output module 31 and the non-enable output module 32 to be turned on and turned off.

FIG. 6 is a schematic view of a pixel circuit according to an embodiment of the present application.

In some embodiments of the present application, referring to FIG. 6, the display panel 01 includes the pixel circuit 11 and the data wire DL. The pixel circuit 11 includes the drive transistor M0 and the data voltage writing module 111, the drive transistor M0 is configured to generate the driving current, the data voltage writing module 111 is electrically connected to the drive transistor M0 and configured to write the data voltage to the drive transistor M0, the magnitude of the driving current generated by the drive transistor M0 is mainly determined by the data voltage received by the drive transistor M0. As shown in FIG. 6, the input terminal of the data voltage writing module 111 is electrically connected to the data wire DL and the data voltage writing module 111 is configured to transmit the data voltage on the data wire DL to the drive transistor M0, so that under a condition that the data voltage writing module 111 is turned on, the data voltage transmitted on the data wire DL is transmitted to one end of the drive transistor M0.

In these embodiments, the first scan wire 21 is electrically connected to the control end of the data voltage writing module 111, so that turning on and turning off the data voltage writing module 111 are controlled by the signal transmitted by the first scan wire 21. The operation process of the pixel circuit 11 includes the data voltage writing stage, and in the data voltage writing stage, the data voltage writing module 111 is turned on. Therefore, in the data voltage writing stage, under a condition that the data voltage writing module 111 needs to transmit the data voltage to the drive transistor M0, the first scan wire 21 should transmit the enable signal to the control end of the data voltage writing module 111; in the non-data voltage writing stage, under a condition that the data voltage writing module 111 stops transmitting the data voltage to the drive transistor M0, the first scan wire 21 should transmit the non-enable signal to the control end of the data voltage writing module 111. Specifically, the first scan wire 21 may be electrically connected to the gate of at least one transistor in the data voltage writing module 111.

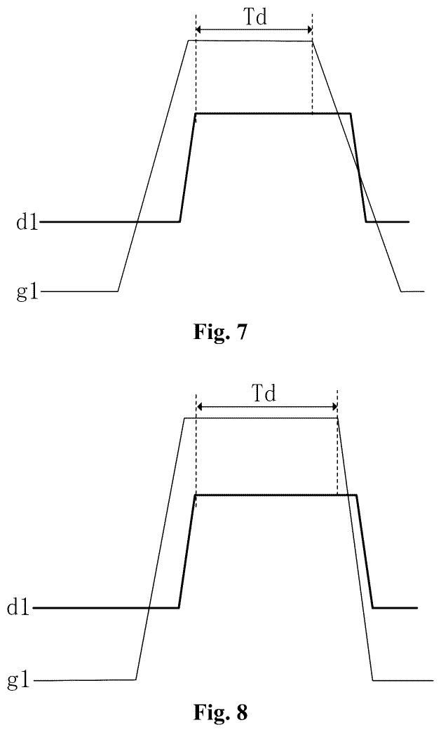

FIG. 7 is an existing operation time sequence diagram corresponding to the pixel circuit shown in FIG. 6.

Referring to FIG. 6 and FIG. 7, the signal of the gate of the transistor electrically connected to the first scan wire 21 in the data voltage writing module 111 is represented by g1; and the signal transmitted by the data wire DL is represented by d1. It may be understood that the signal g1 is transmitted by the first scan wire 21 to the gate of the transistor electrically connected to the first scan wire 21 in the data voltage writing module 111; and the signal d1 is transmitted to the first end of the transistor electrically connected to the first scan wire 21 in the data voltage writing module 111. Referring to FIG. 6 and FIG. 7, under a condition that the pixel circuit 11 finishes the data voltage writing stage Td, the transistor electrically connected to the first scan wire 21 in the data voltage writing module 111 is not immediately turned off, but is gradually turned off in response to the process in which the signal g1 switches from the enable signal to the non-enable signal; under this condition, the signal d1 transmitted by the data wire DL switches from the data voltage required by the pixel circuit 11 (for example, the high level shown in FIG. 7) to other potential (for example, the low potential shown in FIG. 7). As shown in FIG. 7, under a condition that the time length in which the signal g1 switches from the enable signal to the non-enable signal is relatively long, the time length in which the potential of the gate of the transistor electrically connected to the first scan wire 21 in the data voltage writing module 111 switches from the enable signal to the non-enable signal is relatively long; under this condition, there is the problem of data voltage mischarge. As shown in FIG. 7, since the time length in which the potential of the gate of the transistor electrically connected to the first scan wire 21 in the data voltage writing module 111 switches from the enable signal to the non-enable signal is relatively long, under a condition that the signal d1 on the data wire DL has been no longer the data voltage required by the transistor, the transistor is still turned on, so that the incorrect voltage is written to the drive transistor M0, causing the data voltage mischarge.

In the related art, under a condition that the first end of the first scan wire 21 is electrically connected to the shift register 300, and the second end of the first scan wire 21 is suspended, the changing feature that the potential of the gate of the transistor electrically connected to the vicinity of the first end of the first scan wire 21 changes from the enable signal to the non-enable signal is substantially the same as the changing feature of the signal output by the non-enable output module 32 in the switching period T20; since the switching period T20 in which the signal of the non-enable output module 32 changes from the enable signal to the non-enable signal is relatively short, the transistor electrically connected to the first scan wire 21 in the data voltage writing module 111 in the vicinity of the first end of the first scan wire 21 can be instantly turned off. However, due to the voltage drop and the delay, referring to FIG. 7, the start moment at which the potential of the gate of the transistor electrically connected to the vicinity of the second end of the first scan wire 21 starts switching from the enable signal to the non-enable signal is relatively late, and the time length in which the potential of the gate of the transistor electrically connected to the vicinity of the second end of the first scan wire 21 changes from the enable signal to the non-enable signal is significantly increased, so that the risk of the data voltage mischarge of the pixel 10 electrically connected to the far end of the first scan wire 21 is significantly increased. Also, under a condition that the display panel 01 is in a high-frequency display, the time length of the data voltage writing stage Td is shorter, and the problem of data voltage mischarge is more obvious.

FIG. 8 is an operation time sequence diagram corresponding to the pixel circuit shown in FIG. 6.

In this embodiment, the second end of the first scan wire 21 is electrically connected to the compensation module 400 in the first compensation module group 40, and the compensation module 400 is turned on in the switching period T20 in which the shift register 300 switches from outputting the enable signal to outputting the non-enable signal, so that under a condition that the transistor electrically connected to the first scan wire 21 in the data voltage writing module 111 in the vicinity of the first end of the first scan wire 21 starts to be turned off, the transistor electrically connected to the first scan wire 21 in the data voltage writing module 111 in the vicinity of the second end of the second scan wire 20 basically starts to be turned off; the time length in which the transistor electrically connected to the first scan wire 21 in the data voltage writing module 111 in the vicinity of the first end of the first scan wire 21 switches from being turned on to being turned off is substantially equal to the time length in which the transistor electrically connected to the first scan wire 21 in the data voltage writing module 111 in the vicinity of the second end of the first scan wire 21 switches from being turned on to being turned off.

FIG. 8 is a part of the operation time sequence of the transistor electrically connected to the first scan wire 21 in the data voltage writing module 111 in the vicinity of the second end of the first scan wire 21 in the display panel 01 using the technical solutions of the present application. Comparing FIG. 8 to FIG. 7, with the technical solutions of the present application, in the data voltage writing module 111 in the vicinity of the second end of the first scan wire 21, the time length in which the signal g of the gate of the transistor electrically connected to the first scan wire 21 changes from the high level to the low level is significantly reduced, so that the time length in which the transistor switches from being turned on to being turned off is significantly shortened, and the risk that the transistor is erroneously turned on is significantly reduced. Therefore, the problem of data voltage mischarge of the pixel circuit 11 in the vicinity of the second end of the first scan wire 21 is effectively reduced, and the display effect of the display panel 01 is improved.

In a technical solution corresponding to these embodiments, the data voltage writing module 111 includes the N-channel transistor, and the first scan wire 21 is electrically connected to the gate of the N-channel transistor in the data voltage writing module 111. The enable signal received and transmitted by the first scan wire 21 is the high level, and the non-enable signal is the low level; the enable signal output by the shift register 300 is the high level, and the non-enable signal is the low level.

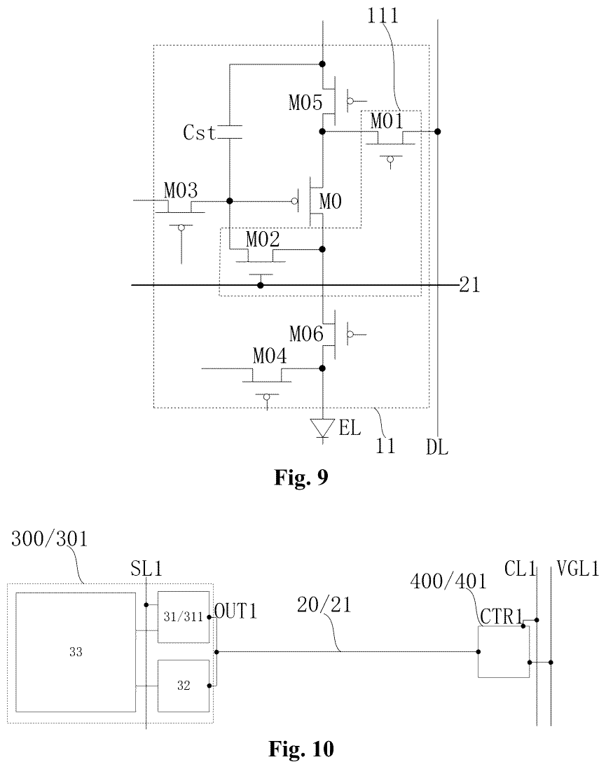

FIG. 9 is an equivalent circuit diagram of the pixel circuit corresponding to FIG. 6.

As shown in FIG. 9, the data voltage writing module 111 includes the data voltage writing transistor M01 and the threshold grasping transistor M02; the first end of the data voltage writing transistor M01 is electrically connected to the data wire DL, and the second end of the data voltage writing transistor M01 is electrically connected to the first end of the drive transistor M0; the first end of the threshold grasping transistor M02 is electrically connected to the second end of the drive transistor M0, the second end of the threshold grasping transistor M02 is electrically connected to the gate of the drive transistor M0, and the gate of the threshold grasping transistor M02 is electrically connected to the first scan wire 21. In the data voltage writing stage Td of the pixel circuit 11, the data voltage writing transistor M01 and the threshold grasping transistor M02 are turned on, and the data voltage transmitted on the data wire DL is written to the gate of the drive transistor M0 by the data voltage writing transistor M01, the threshold grasping transistor M02, and the drive transistor M0 which are turned on. The first scan wire 21 is electrically connected to the gate of the threshold grasping transistor M02, so that in the data voltage writing stage Td of the pixel circuit 11, the first scan wire 21 transmits the enable signal to control the threshold grasping transistor M02 to be turned on; in the non-data voltage writing stage of the pixel circuit 11, the first scan wire 21 transmits the non-enable signal to control the threshold grasping transistor M02 to be turned off. In some embodiments, the threshold grasping transistor M02 may be the N-channel transistor; under a condition that the N-channel transistor is used in the threshold grasping transistor M02, the problem that the light-emitting brightness of the light-emitting device is not ideal due to the change of the potential of the gate of the drive transistor M0 caused by the current leakage may be effectively reduced.

As shown in FIG. 9, the data voltage writing transistor M01 may be the P-channel transistor, so that the gate of the data voltage writing transistor M01 and the gate of the threshold grasping transistor M02 may be electrically connected to different scan wires 20. In some embodiments, the data voltage writing transistor M01 may be the N-channel transistor, so that the gate of the data voltage writing transistor M01 and the gate of the threshold grasping transistor M02 may be electrically connected to the first scan wire 21 at the same time.

As shown in FIG. 9, the pixel circuit 11 may further include the first reset transistor M03, the second reset transistor M04, the power supply voltage writing transistor M05, the light-emitting control transistor M06, and the storage capacitor Cst, and the storage capacitor Cst is electrically connected to the gate of the drive transistor M0.

The first end of the first reset transistor M03 is electrically connected to the reset signal wire, the second end of the first reset transistor M03 is electrically connected to the gate of the drive transistor M0, the first end of the second reset transistor M04 is electrically connected to the reset signal wire, and the second end of the second reset transistor M04 is electrically connected to the output terminal of the pixel circuit 11; the first reset transistor M03 and the second reset transistor M04 may be turned on in the reset stage of the pixel circuit 11, and reset the gate of the drive transistor M0 and the output terminal of the pixel circuit 11, respectively. In some embodiments, at least one of the gate of the first reset transistor M03 or the gate of the second reset transistor M04 may be electrically connected to the first scan wire 21, the first end of the first scan wire 21 may be electrically connected to the first shift register 301, and the second end of the first scan wire 21 may be electrically connected to the first compensation module 401, so as to improve the reset effect of the pixel circuit 11 in the vicinity of the first end and the second end of the first scan wire 21.

The first end of the power supply voltage writing transistor M05 is electrically connected to the first power supply voltage wire, the second end of the power supply voltage writing transistor M05 is electrically connected to the first end of the drive transistor M0, the first end of the light-emitting control transistor M06 is electrically connected to the second end of the drive transistor M0, the second end of the light-emitting control transistor M06 may be electrically connected to the light-emitting device as the output terminal of the pixel circuit 11, and in the light-emitting stage of the pixel circuit 11, the power supply voltage writing transistor M05 and the light-emitting control transistor M06 may be turned on and control the drive transistor M0 to generate the driving current. In some embodiments, at least one of the gate of the power supply voltage writing transistor M05 or the gate of the light-emitting control transistor M06 may be electrically connected to the first scan wire 21, the first end of the first scan wire 21 may be electrically connected to the first shift register 301, and the second end of the first scan wire 21 may be electrically connected to the first compensation module 401, so as to improve the light-emitting uniformity of the pixel circuit 11 in the vicinity of the first end and the second end of the first scan wire 21.

Further, the output terminal of the light-emitting control transistor M06 may be electrically connected to the light-emitting device EL, and the light-emitting device EL may be at least one of the organic light-emitting diode (OLED), the Micro-LED, or the Mini-LED.

It should be noted that, FIG. 9 only shows one possible pixel circuit 11 according to the embodiments of the present application, and in the real product, the pixel circuit 11 may be the pixel circuit 11 having other structures.

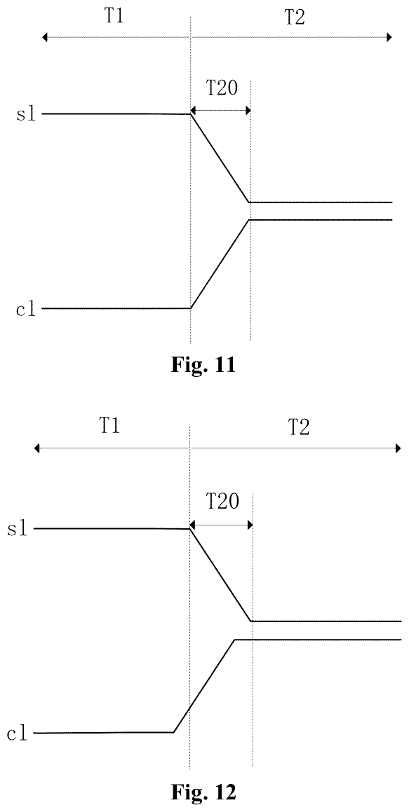

FIG. 10 is a schematic view of a connection of a shift register and a compensation module to a first scan wire according to an embodiment of the present application, and FIG. 11 is an operation time sequence diagram corresponding to FIG. 10.

In some embodiments of the present application, referring to FIG. 10, the display panel 01 further includes the first signal wire SL1 and the first control wire CL1.

The input terminal of the enable output module 31 of the shift register 300 in the first scan drive circuit 30 is electrically connected to the first signal wire SL1, and the enable output module 31 is configured to transmit the signal on the first signal wire SL1 to the first scan wire 21 under a condition that the enable output module 31 is turned on. The signal transmitted on the first signal wire SL1 is represented by sl. Referring to FIG. 10 and FIG. 11, the first signal wire SL1 may transmit the enable signal in the enable stage T1 of the shift register 300 electrically connected to the first signal wire SL1, may switch from transmitting the enable signal to transmitting the non-enable signal in the switching period T20 in the non-enable stage T2 of the shift register 300 electrically connected to the first signal wire SL1, and may transmit the non-enable signal in other periods after the switching period T20 in the non-enable stage T2 of the shift register 300 electrically connected to the first signal wire SL1.

The first control wire CL1 is electrically connected to the control end of the compensation module 400 in the first compensation module group 40, the active level signal transmitted by the first control wire CL1 controls the compensation module 400 to be turned on, and the inactive level signal transmitted by the first control wire CL1 controls the compensation module 400 to be turned off. The signal transmitted on the first control wire CL1 is represented by cl. Unless otherwise specified, the example in which the active level signal is at the high level is given for illustration; under a condition that the first control wire CL1 transmits the high level, the first compensation module 401 is turned on; and under a condition that the first control wire CL1 transmits the low level, the first compensation module 401 is turned off.

In the embodiments of the present application, in the first control wire CL1 and the first signal wire SL1 electrically connected respectively to the shift register 300 in the first scan drive circuit 30 and the compensation module 400 in the first compensation module group 40 electrically connected to the same first scan wire 21, and in the switching period T20, the signal on the first control wire CL1 is the active level signal before the signal on the first signal wire SL1 changes to the non-enable signal. For example, referring to FIG. 10 and FIG. 12, in the first signal wire SL1 and the first control wire CL1 electrically connected respectively to the first enable output module 311 and the first compensation module 401 electrically connected to the same first scan wire 21, before the signal sl on the first signal wire SL1 changes to the low level in the switching period T20, the signal cl on the first control wire CL1 has been the high level. In this way, in the first shift register 301 and the first compensation module 401 electrically connected to the same first scan wire 21, the first compensation module 401 has been turned on before the first shift register 301 finishes the switching period T20.

In some possible embodiments, in the first control wire CL1 and the first signal wire SL1 electrically connected respectively to the shift register 300 in the first scan drive circuit 30 and the compensation module 400 in the first compensation module group 40 electrically connected to the same first scan wire 21, and in the switching period T20, the start moment at which the signal cl on the first control wire CL1 switches from the inactive level signal to the active level signal is the same as the start moment at which the signal sl on the first signal wire SL1 switches from the enable signal to the non-enable signal. For example, referring to FIG. 10 and FIG. 11, in the first signal wire SL1 and the first control wire CL1 electrically connected respectively to the first enable output module 311 and the first compensation module 401 electrically connected to the same first scan wire 21, and in the switching period T20, the moment at which the signal cl on the first control wire CL1 starts switching from the low level to the high level is the same as the moment at which the signal sl on the first signal wire SL1 starts switching from the high level to the low level. In this way, in the first shift register 301 and the first compensation module 401 electrically connected to the same first scan wire 21, the first compensation module 401 has been turned on before the first shift register 301 finishes the switching period T20.

In this embodiment, the changing moment of the signal transmitted by the first signal wire SL1 is the same as the changing moment of the signal transmitted by the first control wire CL1; the difficulty of generating the two signals is small, and the computing power of the driving module is reduced.

FIG. 12 is another operation time sequence diagram corresponding to FIG. 10.

In some possible embodiments, in the first control wire CL1 and the first signal wire SL1 electrically connected respectively to the shift register 300 in the first scan drive circuit 30 and the compensation module 400 in the first compensation module group 40 electrically connected to the same first scan wire 21, and before the switching period T20 start, the signal cl on the first control wire CL1 starts switching from the inactive level signal to the active level signal. The compensation module 400 may include the transistor; considering the time length in which the transistor switches from being turned off to being turned on, the moment at which the signal c1 on the first control wire CL1 starts switching from the inactive level signal to the active level is provided before the switching period T20, so that it is ensured that under a condition that the potential of the first end of the first scan wire 21 starts changing in the non-enable stage T2, the compensation module 400 electrically connected to the first scan wire 21 has been turned on, and the potential of the second end of the first scan wire 21 starts changing. For example, referring to FIG. 10 and FIG. 12, in the first signal wire SL1 and the first control wire CL1 electrically connected respectively to the first enable output module 311 and the first compensation module 401 electrically connected to the same first scan wire 21, the moment at which the signal cl on the first control wire CL1 starts switching from the low level to the high level is slightly earlier than the moment at which the signal sl on the first signal wire SL1 starts switching from the low level to the high level in the switching period T20.

Considering the time length in which the transistor switches from being turned off to being turned on, under a condition that the moment at which the signal cl on the first control wire CL1 starts switching from the low level to the high level is slightly earlier than the moment at which the signal sl on the first signal wire SL1 starts switching from the low level to the high level in the switching period T20, the first compensation module 401 may be turned on as early as possible in the switching period T20 of the corresponding first shift register 301, so as to ensure that the second end of the first scan wire 21 can start switching to the non-enable signal as early as possible in the switching period T20.

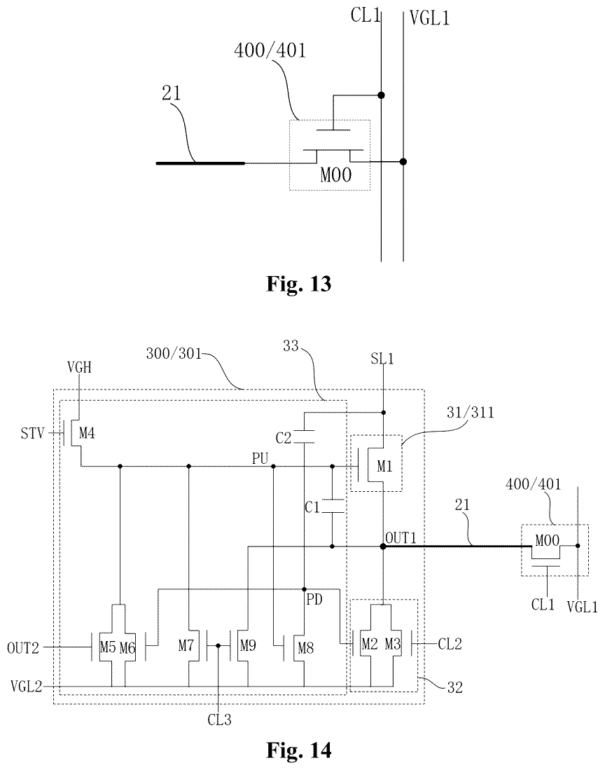

FIG. 13 is an equivalent circuit diagram of a compensation module according to an embodiment of the present application.

In some embodiments of the present application, as shown in FIG. 13, the compensation module 400 in the first compensation module group 40 includes the compensation transistor M00, the compensation transistor M00 is the N-channel transistor, and the gate of the compensation transistor M00 is electrically connected to the first control wire CL1. Since the N-channel transistor is turned on under a condition that the gate of the N-channel transistor receives the high level, and the N-channel transistor is turned off under a condition that the gate of the N-channel transistor receives the low level, the high level transmitted by the first control wire CL1 is the active level signal and the low level transmitted by the first control wire CL1 is the inactive level signal.

In some possible embodiments, the first scan wire 21 is electrically connected to the gate of the N-channel transistor in the data voltage writing module 111, and since the N-channel transistor is turned on under a condition that the gate of the N-channel transistor receives the high level, and the N-channel transistor is turned off under a condition that the gate of the N-channel transistor receives the low level, the high level transmitted by the first scan wire 21 is the enable signal, and the low level transmitted by the first scan wire 21 is the non-enable signal; and correspondingly, the high level transmitted by the first signal wire SL1 is the enable signal, and the low level transmitted by the first signal wire SL1 is the non-enable signal.

Referring to FIG. 13, FIG. 11, and FIG. 12, in the first control wire CL1 and the first signal wire SL1 electrically connected respectively to the shift register 300 in the first scan drive circuit 30 and the compensation module 400 in the first compensation module group 40 electrically connected to the same first scan wire 21, and in the switching period T20, the rising edge of the signal cl transmitted by the first control wire CL1 and the falling edge of the signal sl transmitted by the first signal wire SL1 at least partially overlap. That is, in the first signal wire SL1 and the first control wire CL1 electrically connected respectively to the first enable output module 311 and the first compensation module 401 electrically connected to the same first scan wire 21, and in the switching period T20, the rising edge of the signal cl transmitted by the first control wire CL1 and the falling edge of the signal sl transmitted by the first signal wire SL1 at least partially overlap. Therefore, in the process in which the potential of the first end of the first scan wire 21 switches from the enable signal to the non-enable signal, the potential of the second end of the first scan wire 21 switches from the enable signal to the non-enable signal.

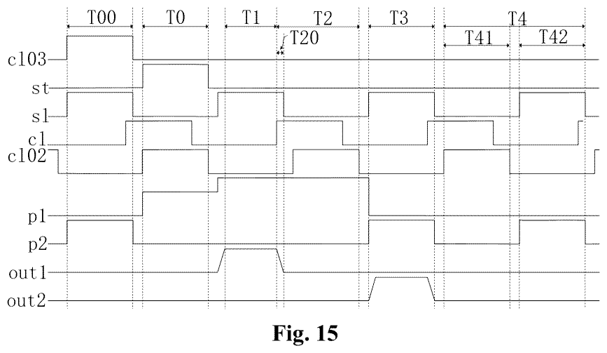

FIG. 14 is an equivalent circuit diagram of a shift register and a compensation module according to an embodiment of the present application, and FIG. 15 is an operation time sequence diagram corresponding to FIG. 14.

In some embodiments of the present application, as shown in FIG. 14, the enable output module 31 of the shift register 300 includes the first transistor M1, the input terminal of the first transistor M1 is electrically connected to the first signal wire SL1, the output terminal of the first transistor M1 is electrically connected to the first end of the first scan wire 21, and the gate of the first transistor M1 is electrically connected to the first node PU. The non-enable output module 32 of the shift register 300 includes the second transistor M2 and the third transistor M3, the input terminals of the second transistor M2 and the third transistor M3 are both electrically connected to the second non-enable signal wire VGL2, the output terminals of the second transistor M2 and the third transistor M3 are electrically connected to the first end of the first scan wire 21, the gate of the second transistor M2 is electrically connected to the second node PD, and the gate of the third transistor M3 is electrically connected to the second control wire CL2. The control module 33 includes the fourth transistor M4, the fifth transistor M5, the sixth transistor M6, the seventh transistor M7, and the first capacitor C1; the input terminal of the fourth transistor M4 is electrically connected to the enable signal wire VGH, the output terminal of the fourth transistor M4 is electrically connected to the first node PU, and the gate of the fourth transistor M4 is electrically connected to the trigger end STV; the input terminal of the fifth transistor M5 is electrically connected to the second non-enable signal wire VGL2, the output terminal of the fifth transistor M5 is electrically connected to the first node PU, and the gate of the fifth transistor M5 is electrically connected to the output terminal of the next stage of shift register 300; the input terminal of the sixth transistor M6 is electrically connected to the second non-enable signal wire VGL2, the output terminal of the sixth transistor M6 is electrically connected to the first node PU, and the gate of the sixth transistor M6 is electrically connected to the second node PD; the input terminal of the seventh transistor M7 is electrically connected to the second non-enable signal wire VGL2, the output terminal of the seventh transistor M7 is electrically connected to the first node PU, and the gate of the seventh transistor M7 is electrically connected to the third control wire CL3; the first plate of the first capacitor C1 is electrically connected to the first node PU, and the second plate of the first capacitor C1 is electrically connected to the output terminal of the first transistor M1. The control module 33 further includes the eighth transistor M8, the ninth transistor M9, and the second capacitor C2; the input terminal of the eighth transistor M8 is electrically connected to the second non-enable signal wire VGL2, the output terminal of the eighth transistor M8 is electrically connected to the second node PD, and the gate of the eighth transistor M8 is electrically connected to the first node PU; the input terminal of the ninth transistor M9 is electrically connected to the second non-enable signal wire VGL2, the output terminal of the ninth transistor M9 is electrically connected to the first end of the first scan wire 21, and the gate of the ninth transistor M9 is electrically connected to the third control wire CL3; the first plate of the second capacitor C2 is electrically connected to the first signal wire SL1, and the second plate of the second capacitor C2 is electrically connected to the second node PD. Under a condition that the shift register 300 is the first stage of shift register 300 in the scan drive circuit, the trigger end STV corresponding to the shift register 300 is the trigger signal wire; under a condition that the shift register 300 is not the first stage of shift register 300 in the scan drive circuit, the trigger end STV corresponding to the shift register 300 may be the output terminal of the previous stage of shift register 300.

The compensation module 400 includes the compensation transistor M00, the input terminal of the compensation transistor M00 is electrically connected to the first non-enable signal wire VGL1, the output terminal of the compensation transistor M00 is electrically connected to the second end of the first scan wire 21, and the gate of the compensation transistor M00 is electrically connected to the first control wire CL1.

As shown in FIG. 14, the first transistor M1 to the ninth transistor M9, and the compensation transistor M00 may all be the N-channel transistors, so that for the first transistor M1 to the ninth transistor M9, and the compensation transistor M00, the active level signals for controlling them to be turned on are the high level signals, and the inactive level signals for controlling them to be turned off are the low level signals.

Further, at least a part of the first transistor M1 to the ninth transistor M9, and the compensation transistor M00 may be the P-channel transistors. It should be noted that FIG. 14 shows only the equivalent circuit diagram of the shift register 300 and the compensation module 400, and the shift register 300 and the compensation module 400 may have other forms of equivalent circuit diagrams. Further, the shift register 300 shown in FIG. 14 may be the equivalent circuit diagram of the first shift register 301, and the compensation module 400 shown in FIG. 14 may be the equivalent circuit diagram of the first compensation module 401.

In this embodiment, the shift register 300 and the compensation module 400 shown in FIG. 14 are given as an example for illustration. Further, the signal of the first node PU is represented by p1, the signal of the second node PD is represented by p2, the signal on the first control wire CL1 is represented by cl, the signal on the second control wire CL2 is represented by cl02, the signal on the third control wire CL3 is represented by cl03, the signal on the trigger end STV is represented by st, the signal on the first signal wire is represented by sl, the signal output by the output terminal OUT1 of the current stage of shift register 300 is represented by out1, and the signal output by the output terminal OUT2 of the next stage of shift register 300 is represented by out2. The operation process of the first shift register 301 is described with reference to FIG. 14 and FIG. 15.

Referring to FIG. 14 and FIG. 15, the shift register 300 includes the reset stage T00, the trigger stage T0, the enable stage T1, the non-enable stage T2, the OFF stage T3, and the maintaining stage T4.

In the reset stage T00, the signal transmitted by the third control wire CL3 is the high level, so that the seventh transistor M7 and the ninth transistor M9 are both turned on, the potential of the first node PU is at the low level, and the potential of the first end of the first scan wire 21 is also at the low level; further, the second node PD maintains the high level, so that the second transistor M2 and the sixth transistor M6 are turned on, but the low level potential of the first node PU and the low level potential of the output terminal OUT1 of the shift register 300 are not changed. It should be noted that, the shift registers 300 in the first scan drive circuit 30 all may enter the reset stage T00 at the same time.

In the trigger stage T0, the trigger end STV receives the high level, the fourth transistor M4 is turned on, and the fourth transistor M4 which is turned on outputs the high level to the first node PU. Based on the high level of the first node PU, the first transistor M1 and the eighth transistor M8 are turned on; under this condition, the first signal wire SL1 transmits the low level signal, so that the output terminal OUT1 of the shift register 300 maintains outputting the low level to the first end of the first scan wire 21, the eighth transistor M8 which is turned on outputs the low level to the second node PD, and the second transistor M2 and the sixth transistor M6 are turned off. Further, in the trigger stage T0, the first control wire CL1 and the second control wire CL2 may transmit the high level signal, and the compensation transistor M00 and the third transistor M3 are turned on, so that the output terminal OUT1 of the shift register 300 maintains outputting the low level to the first end of the first scan wire 21, and the compensation module outputs the low level to the second end of the first scan wire 21.

In the enable stage T1, the trigger end STV receives the low level, so that the fourth transistor M4 is turned off, and the first capacitor C1 causes the first node PU to maintain the high level; therefore, the first transistor M1 and the eighth transistor M8 are maintained in the ON state, and the eighth transistor M8 which is turned on causes the second node PD to maintain the stable low level. Under this condition, the signal sl transmitted by the first signal wire SL1 switches to the high level, the output terminal of the first transistor M1 which is turned on outputs the high level, the potential of the first node PU is further pulled up by the coupling effect of the first capacitor C1, and the output terminal OUT1 of the shift register 300 outputs the high level to the first end of the first scan wire 21.

In the non-enable stage T2, the first node PU maintains the high level, so that the first transistor M1 and the eighth transistor M8 are maintained in the ON state, and the signal sl transmitted on the first signal wire SL1 switches from the high level to the low level in this stage; then the signal output from the output terminal OUT1 of the shift register 300 to the first end of the first scan wire 21 switches from the high level to the low level. Further, in order to avoid the interference between different signals, the second control wire CL2 starts transmitting the high level only after a period of time that the non-enable stage T2 starts, so that in the initial stage of the non-enable stage T2, the charge on the first scan wire 21 is discharged and the signal on the first scan wire 21 is switched to the non-enable signal in time mainly relying on the first transistor M1 which is turned on. In the non-enable stage T2, the first control wire CL1 also transmits the high level to control the compensation transistor M00 to be turned on and transmit the low level to the second end of the first scan wire 21. In order to ensure that the second end of the first scan wire 21 can switch from the high level to the low level in time, before the switching period T20 of the non-enable stage T2 ends, the signal cl on the first control wire CL1 has been the high level, and at this moment, the signal sl on the first signal wire SL1 has not completely changed to the low level. The specific situation for the signal cl on the first control wire CL1 and the signal sl on the first signal wire SL1 in the switching period T20 may be as shown in FIG. 11 and FIG. 12, which is not repeated herein.

In the OFF stage T3, the output terminal OUT2 of the next stage of shift register 300 outputs the high level signal, so that the fifth transistor M5 is turned on, and the fifth transistor M5 which is turned on transmits the low level to the first node PU. Further, the signal sl transmitted on the first signal wire SL1 switches from the low level to the high level, the potential of the first node PD changes to the high level by the coupling effect of the second capacitor C2, the second transistor M2 and the sixth transistor M6 are turned on, and the output terminal OUT1 of the shift register 300 outputs the low level to the first end of the first scan wire 21.

The maintaining stage T4 includes the first maintaining stage T41 and the second maintaining stage T42 which are alternately carried out. In the first maintaining stage T41, the second control wire CL2 transmits the high level, so that the third transistor M3 is turned on, and the third transistor M3 which is turned on causes the output terminal OUT1 of the shift register 300 to output the low level to the first end of the first scan wire 21. In the second maintaining stage T42, the signal sl transmitted on the first signal wire SL1 switches to the high level again, the potential of the first node PD changes to the high level by the coupling effect of the second capacitor C2, the second transistor M2 and the sixth transistor M6 are turned on, and the output terminal OUT1 of the shift register 300 outputs the low level to the first end of the first scan wire 21. The signal sl transmitted on the first signal wire SL1 and the signal cl02 transmitted on the second control wire CL2 are both the periodic pulse signals, so that the first maintaining stage T41 and the second maintaining stage T42 are alternately carried out.

In some embodiments of the present application, as shown in FIG. 3, the display panel 01 includes the display region AA, the first compensation module group 40 and the first scan drive circuit 30 are located at two opposite sides of the display region AA along the first direction X, and the first direction X is parallel to the extending direction of the first scan wire 21. For example, as shown in FIG. 3, the first scan wire 21 extends substantially along the row direction, so that one of the first scan drive circuit 30 and the first compensation module group 40 is located at the left side of the display region AA and the other of the first scan drive circuit 30 and the first compensation module group 40 is located at the right side of the display region AA.

The first compensation module group 40 and the first scan drive circuit 30 are located at two opposite sides of the display region AA along the direction parallel to the extending direction of the first scan wire 21, respectively. The shift register 300 in the first scan drive circuit 30 may be adjacent to the first end of the first scan wire 21, so that it is convenient for the output terminal of the first enable output module 311 to be electrically connected to the first end of the first scan wire 21; the compensation module 400 in the first compensation module group 40 may be adjacent to the second end of the first scan wire 21, so that it is convenient for the output terminal of the first compensation module 401 to be electrically connected to the second end of the first scan wire 21. The difficulty of connecting the first shift register 301 and the first compensation module 401 to the first scan wire 21 is small, and the wiring difficulty is small. Further, the path along which the signal output by the first shift register 301 is transmitted to the first scan wire is short, and the path along which the signal output by the first compensation module 401 is transmitted to the first scan wire 21 is short, so that the signal delay and the voltage drop are reduced.

In some possible embodiments, the first scan wires 21 are all electrically connected to the shift registers 300 in the first scan drive circuit 30; as shown in FIG. 3, the shift registers 300 electrically connected to the first scan wires 21 are all located at the same side of the display region AA; for example, as shown in FIG. 3, the shift registers 300 electrically connected to the first scan wires 21 are all located at the left side of the display region AA.

In these embodiments, the first compensation modules 401 electrically connected to the first scan wires 21 are also located at the same side of the display region AA. For example, as shown in FIG. 3, the compensation modules 400 electrically connected to the first scan wires 21 are all located at the right side of the display region AA.

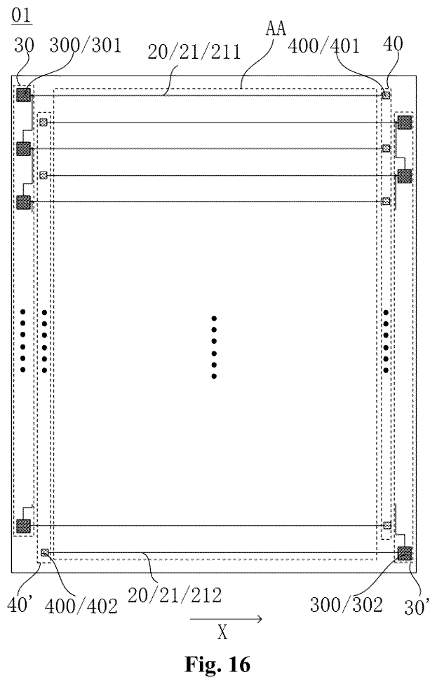

FIG. 16 is a schematic view of a display panel according to an embodiment of the present application.

In some embodiments, as shown in FIG. 16, the display panel 01 further includes the second scan drive circuit 30′, and the second scan drive circuit 30′ may include a plurality of stages of shift registers 300 in a cascaded connection. For convenience of description, the shift register 300 in the second scan drive circuit 30′ is referred to as the second shift register 302.

Referring to FIG. 16, the first ends of a part of the first scan wires 21 are electrically connected to the output terminals of the second shift registers 302 and the first ends of a part of the first scan wires 21 are electrically connected to the output terminals of the first shift registers 301; the first scan drive circuit 30 and the second scan drive circuit 30′ are located at two opposite sides of the display region AA along the direction parallel to the extending direction of the first scan wire 21, respectively. For example, as shown in FIG. 16, the first scan drive circuit 30 and the second scan drive circuit 30′ are located at the left side and the right side of the display region AA, respectively.

In these embodiments, correspondingly, the display panel 01 may further include the second compensation module group 40′, and the second compensation module group 40′ may include a plurality of compensation modules 400. For convenience of description, the compensation module 400 in the second compensation module group 40′ is referred to as the second compensation module 402. The second end of the first scan wire 21 electrically connected to the second shift register 302 is electrically connected to the second compensation module 402; the first compensation module group 40 and the second compensation module group 40′ are located at two opposite sides of the display region AA along the direction parallel to the extending direction of the first scan wire 21, respectively. For example, as shown in FIG. 16, the first scan drive circuit 30 and the second compensation module group 40′ are located at the left side of the display region AA, and the second scan drive circuit 30′ and the first compensation module group 40 are located at the right side of the display region AA.

The shift register 300 in the second scan drive circuit 30′ may include the enable output module 31, the enable output module 31 in the shift register 300 in the second scan drive circuit 30′ is referred to as the second enable output module, and the output terminal of the second enable output module is electrically connected to the first scan wire 21.

As shown in FIG. 16, the first scan wire 21 includes the first sub-scan wire 211 and the second sub-scan wire 212, that is, a part of the first scan wire 21 is the first sub-scan wire 211, and a part of the first scan wire 21 is the second sub-scan wire 212. The display panel 01 further includes the second compensation module group 40′, the second scan drive circuit 30′ includes the plurality of stages of shift registers 300 in a cascaded connection, and the second compensation module group 40′ includes the plurality of compensation modules 400. For convenience of description, the shift register 300 in the second scan drive circuit 30′ is referred to as the second shift register 302, and the compensation module 400 in the second compensation module group 40′ is referred to as the second compensation module 402. The first scan drive circuit 30 and the second compensation module group 40′ are located at the same side of the display region AA, the second scan drive circuit 30′ and the first compensation module group 40 are located at the same side of the display region AA, and the first scan drive circuit 30 and the second scan drive circuit 30′ are located at two opposite sides of the display region AA. For example, as shown in FIG. 16, the first scan drive circuit 30 and the second compensation module group 40′ are located at the left side of the display region AA, and the second scan drive circuit 30′ and the first compensation module 401 are located at the right side of the display region AA. The output terminal of the enable output module 31 in the first scan drive circuit 30 is electrically connected to the first end of the first sub-scan wire 211, and the output terminal of the compensation module 400 in the first compensation module group 40 is electrically connected to the second end of the first sub-scan wire 211; the output terminal of the enable output module 31 in the second scan drive circuit 30′ is electrically connected to the first end of the second sub-scan wire 212, and the output terminal of the compensation module 400 in the first compensation module group 40 is electrically connected to the second end of the second sub-scan wire 212. That is, the output terminal of the first enable output module 311 is electrically connected to the first end of the first sub-scan wire 211, and the output terminal of the first compensation module 401 is electrically connected to the second end of the first sub-scan wire 211; the output terminal of the second enable output module 31 is electrically connected to the first end of the second sub-scan wire 212, and the output terminal of the second compensation module 402 is electrically connected to the second end of the second sub-scan wire 212.

The second shift register 302 and the first shift register 301 in these embodiments are configured to provide the enable signal and the non-enable signal to the first scan wire 21, and the second compensation module 402 and the first compensation module 401 are configured to switch the second end of the first scan wire 21 from the enable signal to the non-enable signal in time. That is, in these embodiments, the second shift register 302 and the second compensation module 402 may be designed based on the same inventive concept as the first shift register 301 and the first compensation module 401, which is not repeated herein.

In some embodiments, the second shift register 302 in the second scan drive circuit 30′ is not electrically connected to the first scan wire 21, but is electrically connected to other types of scan wires. For example, the scan wire electrically connected to the first shift register 301 in the first scan drive circuit 30 may be electrically connected to the gate of the threshold grasping transistor M02 in the pixel circuit 11, and the scan wire electrically connected to the second shift register 302 in the second scan drive circuit 30′ may be electrically connected to the gate of any one of the first reset transistor M03, the second reset transistor M04, the power supply voltage writing transistor M05, or the light-emitting control transistor M06.

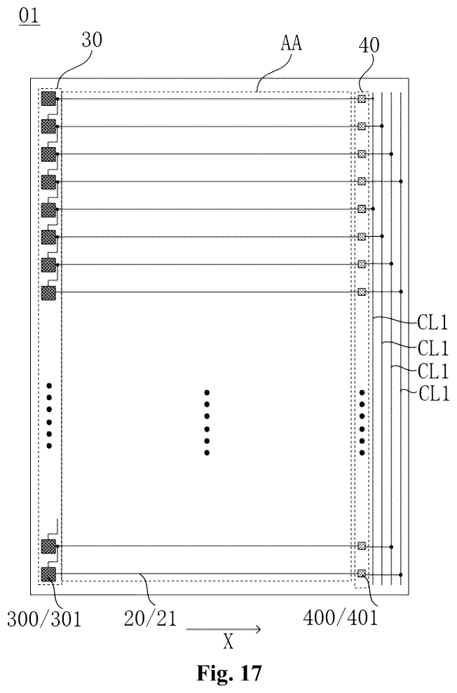

FIG. 17 is a schematic view of a display panel according to an embodiment of the present application.

In some embodiments of the present application, referring to FIG. 17, a part of the compensation modules 400 in the first compensation module group 40 are electrically connected to different first control wires CL1. For example, as shown in FIG. 17, the number of the first control wires CL1 electrically connected to all the compensation modules in the first compensation module group 40 is four; one of the four first control wires CL1 is electrically connected to the control ends of the first one, the fifth one, the ninth one, . . . of the first compensation modules 401 in the first compensation module group 40, one of the four first control wires CL1 is electrically connected to the control ends of the second one, the sixth one, the tenth one, . . . of the first compensation modules 401 in the first compensation module group 40, one of the four first control wires CL1 is electrically connected to the control ends of the third one, the seventh one, the eleventh one, . . . of the first compensation modules 401 in the first compensation module group 40, and one of the four first control wires CL1 is electrically connected to the control ends of the fourth one, the eighth one, the twelfth one, . . . of the first compensation modules 401 in the first compensation module group 40.

The first control wires CL1 electrically connected to at least a part of the compensation modules 400 in the first compensation module group 40 are different from each other, that is, the number of the compensation modules 400 electrically connected to the first control wires CL1 is reduced, so that the load of the first control wires CL1 is relatively small, and these first control wires CL1 can control the compensation modules 400 electrically connected to these first control wires CL1 to switch between the ON state and the OFF state as quickly as possible. That is, the time length in which the second end of the first scan wire 21 switches from the enable signal to the non-enable signal may be reduced.

It may understood that, in order to reduce the number of wires, one first control wire CL1 needs to be electrically connected to a plurality of compensation modules 400 in the first compensation module group 40.

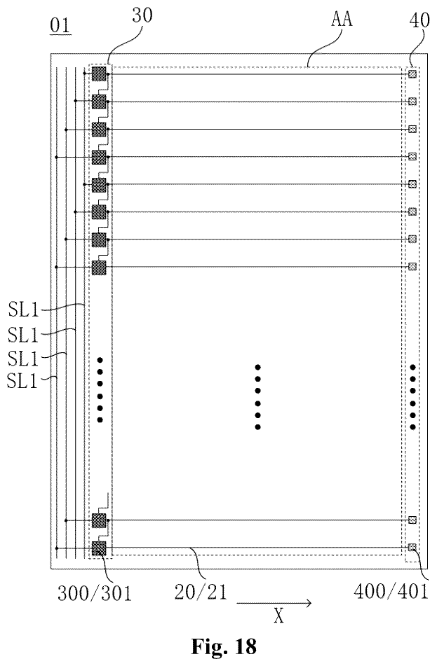

FIG. 18 is a schematic view of a display panel according to an embodiment of the present application.

In some embodiments of the present application, as shown in FIG. 18, a part of the shift registers 300 in the first scan drive circuit 30 are electrically connected to different first signal wires SL1. For example, as shown in FIG. 18, the number of the first signal wires SL1 electrically connected to all the shift registers 300 in the first scan drive circuit 30 is four; one of the four first signal wires SL1 is electrically connected to the input terminals of the first stage, the fifth stage, the ninth stage, . . . of the first shift registers 301 in the shift registers 300, one of the four first signal wires SL1 is electrically connected to the input terminals of the second stage, the sixth stage, the tenth stage, . . . of the first shift registers 301 in the shift registers 300, one of the four first signal wires SL1 is electrically connected to the input terminals of the third stage, the seventh stage, the eleventh stage, . . . of the first shift registers 301 in the shift registers 300, and one of the four first signal wires SL1 is electrically connected to the input terminals of the fourth stage, the eighth stage, the twelfth stage, . . . of the first shift registers 301 in the shift registers 300.

The first signal wires SL1 electrically connected to at least a part of the shift registers 300 in the first scan drive circuit 30 are different from each other, that is, the number of the shift registers 300 electrically connected to the first signal wires SL1 is reduced, so that the load of the first signals is relatively small, and the accuracy of output values of the signals transmitted by these first signals are output from the first enable output module 311 to the first scan wire 21 is ensured.

It may be understood that, in order to reduce the number of wires, one first signal wire SL1 needs to be electrically connected to a plurality of shift registers 300 in the first scan drive circuit 30.

Further, under a condition that the first scan wire 21 is electrically connected to the control end of the data voltage writing module 111 in the pixel circuit 11, the first signal wires SL1 electrically connected to the adjacent stages of shift registers 300 in the first scan drive circuit 30 are different from each other, so that the pre-charging of the data voltage may be achieved. That is, for two adjacent stages of shift registers 300 in the first scan drive circuit 30, in a part of the period in which the previous stage of shift register 300 outputs the enable signal transmitted by the first signal wire SL1 electrically connected to the previous stage of shift register 300 to control the pixel circuit 11 electrically connected to the previous stage of shift register 300 to carry out the data voltage writing, the next stage of shift register 300 may output the enable signal transmitted by the first signal wire SL1 electrically connected to the next stage of shift register 300 to control the data voltage writing module 111 of the pixel circuit 11 electrically connected to the next stage of shift register 300 to be turned on, so as to achieve the pre-charging of the data voltage.

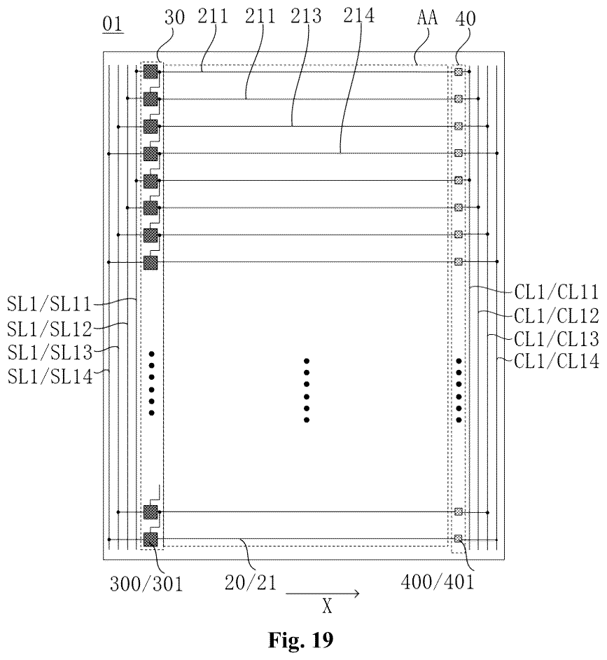

FIG. 19 is a schematic view of a display panel according to an embodiment of the present application.

In some embodiments, the number of the first signal wires SL1 electrically connected to the first scan drive circuit 30 is equal to the number of the first control wires CL1 electrically connected to the first compensation module group 40. For example, as shown in FIG. 19, the number of the first control wires CL1 electrically connected to all the compensation modules in the first compensation module group 40 is four, and the number of the first signal wires SL1 electrically connected to all the shift registers 300 in the first scan drive circuit 30 is four.

Under a condition that one first signal wire SL1 is electrically connected to the first enable output modules 311 in the plurality of shift registers 300 in the first scan drive circuit 30, in order to achieve that these first enable output modules 311 do not output the enable signal at the same time, the first signal wire SL1 should transmit the multi-pulse signal; and under a condition that one first control wire CL1 is electrically connected to the plurality of compensation modules 400 in the first compensation module group 40, in order to achieve that these compensation modules 400 do not output the active level signal at the same time, the first signal wire SL1 should transmit the multi-pulse signal.

Under a condition that the enable signal and the active level signal are both at the high level or the low level, the pulse signals of the first signal wire SL1 and the first control wire CL1 electrically connected respectively to the first enable output module 311 and the first compensation module 401 electrically connected to the same first scan wire 21 may be the same. Under a condition that one of the enable signal and the active level signal is at the high level, and the other of the enable signal and the active level signal is at the low level, the pulse signals of the first signal wire SL1 and the first control wire CL1 electrically connected respectively to the first enable output module 311 and the first compensation module 401 electrically connected to the same first scan wire 21 may be opposite to each other.

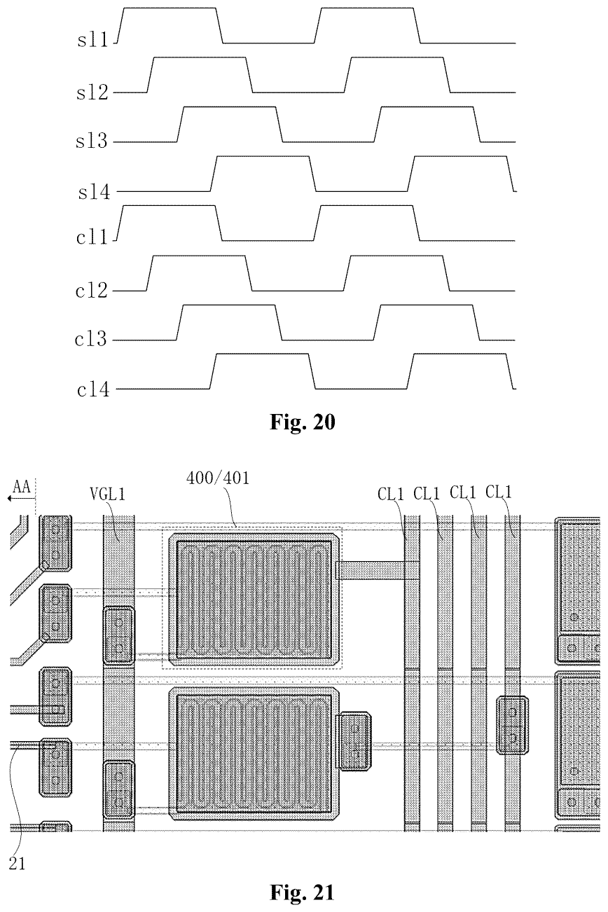

FIG. 20 is an operation time sequence diagram corresponding to FIG. 19.

In an embodiment, referring to FIG. 19 and FIG. 20, the enable signal and the active level signal are both the high level, so that the pulse signals of the first signal wire SL1 and the first control wire CL1 electrically connected respectively to the first enable output module 311 and the first compensation module 401 electrically connected to the same first scan wire 21 may be the same. For example, in FIG. 19 and FIG. 20, in the first enable output module 311 and the first compensation module 401 connected respectively to two ends of the first scan wire 211, the input terminal of the first enable output module 311 is electrically connected to the first signal wire SL11, the control end of the first compensation module 401 is electrically connected to the first control wire CL11, and the pulse signals sl1 and cl1 transmitted respectively by the first signal wire SL11 and the first control wire CL11 are the same; in the first enable output module 311 and the first compensation module 401 connected respectively to two ends of the first scan wire 212, the input terminal of the first enable output module 311 is electrically connected to the first signal wire SL12, the control end of the first compensation module 401 is electrically connected to the first control wire CL12, and the pulse signals sl2 and cl2 transmitted respectively by the first signal wire SL12 and the first control wire CL12 are the same; in the first enable output module 311 and the first compensation module 401 connected respectively to two ends of the first scan wire 213, the input terminal of the first enable output module 311 is electrically connected to the first signal wire SL13, the control end of the first compensation module 401 is electrically connected to the first control wire CL13, and the pulse signals sl3 and cl3 transmitted respectively by the first signal wire SL13 and the first control wire CL13 are the same; in the first enable output module 311 and the first compensation module 401 connected respectively to two ends of the first scan wire 214, the input terminal of the first enable output module 311 is electrically connected to the first signal wire SL14, the control end of the first compensation module 401 is electrically connected to the first control wire CL14, and the pulse signals sl4 and cl4 transmitted respectively by the first signal wire SL14 and the first control wire CL14 are the same.

In this embodiment, the pulse signals of the first signal wire SL1 and the first control wire CL1 electrically connected respectively to the first enable output module 311 and the first compensation module 401 electrically connected to the same first scan wire 21 are the same, so that the computational power of the driving module for driving the display panel 01 to emit light may be reduced.

FIG. 21 is a partial schematic view of a display panel according to an embodiment of the present application.

In some embodiments of the present application, as shown in FIG. 21, in the first control wire CL1 and the first non-enable signal wire VGL1 electrically connected to the first compensation module group 40, the first control wire CL1 and the first non-enable signal wire VGL1 are located at two sides of the first compensation module 401. That is, the first control wire CL1 and the first non-enable signal wire VGL1 electrically connected to the first compensation module 401 are located at two opposite sides of the first compensation module 401, respectively.

As shown in FIG. 21, the first control wire CL1 and the first non-enable signal wire VGL1 are disposed at two opposite sides of the first compensation module group 40, which is conducive to achieving the connection of the first control wire CL1 and the first non-enable signal wire VGL1 to the compensation module 400 in the first compensation module group 40.

In some possible embodiments, as shown in FIG. 21, the first non-enable signal wire VGL1 is located between the first compensation module group 40 and the display region AA, and the first control wire CL1 is located at a side of the first compensation module group 40 away from the display region AA.

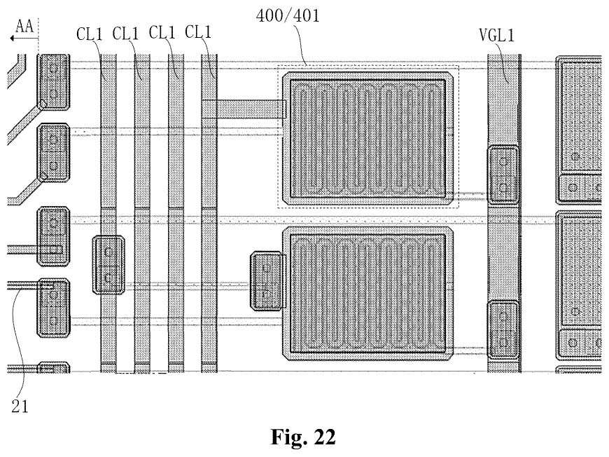

FIG. 22 is a partial schematic view of a display panel according to an embodiment of the present application.

In some possible embodiments, as shown in FIG. 22, the first control wire CL1 is located between the first compensation module group 40 and the display region AA, and the first non-enable signal wire VGL1 is located at a side of the first compensation module group 40 away from the display region AA.

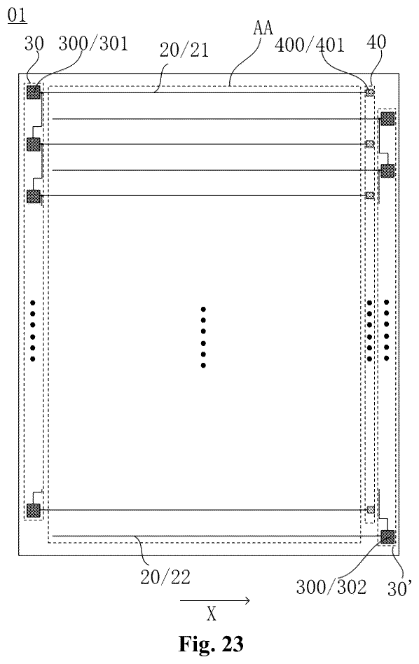

FIG. 23 is a schematic view of a display panel according to an embodiment of the present application.

In some embodiments of the present application, as shown in FIG. 16 and FIG. 23, the display panel 01 further includes the second scan drive circuit 30′, and the second scan drive circuit 30′ also includes a plurality of stages of shift registers 300 in a cascaded connection. However, as shown in FIG. 16, the shift register 300 in the second scan drive circuit 30′ may be electrically connected to the first scan wire 21, and the shift register 300 in the second scan drive circuit 30′ and the shift register 300 in the first scan drive circuit 30 may be electrically connected to different first scan wires 21, respectively, which is not repeated herein. Alternatively, as shown in FIG. 23, the shift register 300 in the second scan drive circuit may be electrically connected to the second scan wire 22 and may be configured to provide the enable signal and/or the non-enable signal to the second scan wire 22, and the type of the transistor electrically connected to the second scan wire 22 is different from the type of the transistor electrically connected to the first scan wire 21; for example, the transistor electrically connected to the second scan wire 22 and the transistor electrically connected to the first scan wire 21 are the transistors in different modules in the pixel circuit 11.

For convenience of description, the shift register 300 in the second scan drive circuit 30′ is referred to as the second shift register 302.

Optionally, as shown in FIG. 16, two ends of the scan wire 20 electrically connected to the second shift register 302 may be electrically connected to the second shift register 302 and the second compensation module 402, respectively. Further, as shown in FIG. 23, one end of the scan wire 20 electrically connected to the second shift register 302 may be electrically connected to the second shift register 302 and the other end may be suspended.

In these embodiments, the display panel 01 includes the display region AA, the second scan drive circuit 30′ and the first compensation module group 40 are located at the same side of the display region AA, and the first compensation module 401 and the first scan drive circuit 30 are located at two opposite sides of the display region AA. For example, as shown in FIG. 16 and FIG. 23, the second scan drive circuit 30′ and the first compensation module group 40 are located at the right side of the display region AA, and the first scan drive circuit 30 is located at the left side of the display region AA.

In some possible embodiments, as shown in FIG. 16 and FIG. 23, the first compensation module group 40 is located at a side of the second scan drive circuit 30′ close to the display region AA. Since the structure of the compensation module 400 in the first compensation module group 40 is generally simple, the area occupied by the compensation module 400 in the display panel 01 is relatively small. The first compensation module group 40 is disposed at a side of the scan drive circuit adjacent thereto close to the display region AA; on the one hand, the difficulty of connecting the compensation module 400 in the first compensation module group 40 to the first scan wire 21 is relatively small, on the other hand, the difficulty of connecting the shift register 300 in the second scan drive circuit 30′ to the first scan wire 21 may not be increased.

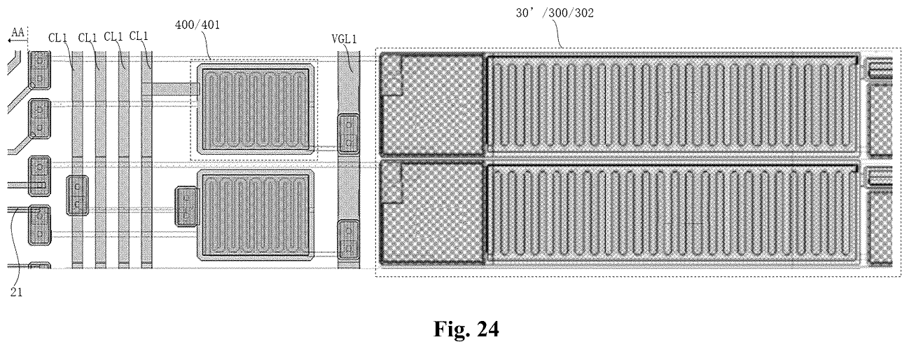

FIG. 24 is a partial schematic view of a display panel according to an embodiment of the present application.

In some possible embodiments, as shown in FIG. 24, the first control wire CL1 is located at a side of the first compensation module group 40 away from the second scan drive circuit 30′. Under a condition that the first compensation module 401 is located between the second scan drive circuit 30′ and the display region AA, the first control wire CL1 is located between the first compensation module group 40 and the display region AA. Under a condition that the first control wire CL1 is located at a side of the first compensation module group 40 away from the second scan drive circuit 30′, the signal crosstalk on the pulse signals of the first control wire CL1 and the second scan drive circuit 30′ may be reduced.

Further, as shown in FIG. 24, under a condition that the first control wire CL1 and the first non-enable signal wire VGL1 are located at two opposite sides of the first compensation module group 40, the first non-enable signal wire VGL1 is located between the first compensation module group 40 and the second scan drive circuit 30′. Therefore, the first non-enable signal wire VGL1 is configured for isolating the signal of the second scan drive circuit 30′ from the signal of the first compensation module group 40, so that the signal interference of the second scan drive circuit 30′ on the compensation module 400 in the first compensation module group 40 can be reduced.

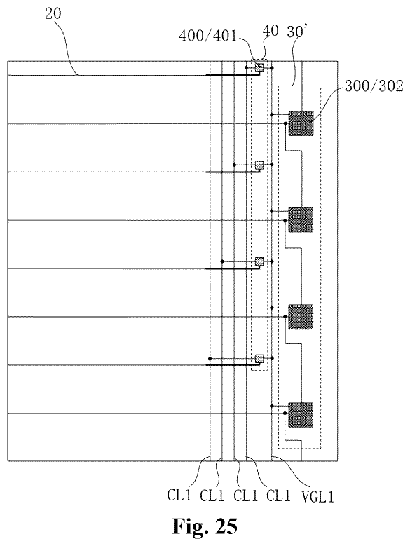

FIG. 25 is a partial schematic view of a display panel according to an embodiment of the present application.

Referring to FIG. 25, under a condition that the first non-enable signal wire VGL1 is located between the first compensation module group 40 and the second scan drive circuit 30′, the first non-enable signal wire VGL1 may be electrically connected to the shift register 300 in the second scan drive circuit 30′. The first non-enable signal wire VGL1 may be electrically connected to the compensation module 400 in the first compensation module group 40 and also the shift register 300 in the second scan drive circuit 30′, that is, the first compensation module group 40 and the second scan drive circuit 30′ share at least a part of the non-enable signal wire, which is conducive to reducing the number of the non-enable signal wires, reducing the dimension of the bezel of the display panel 01, and reducing the wiring difficulty.

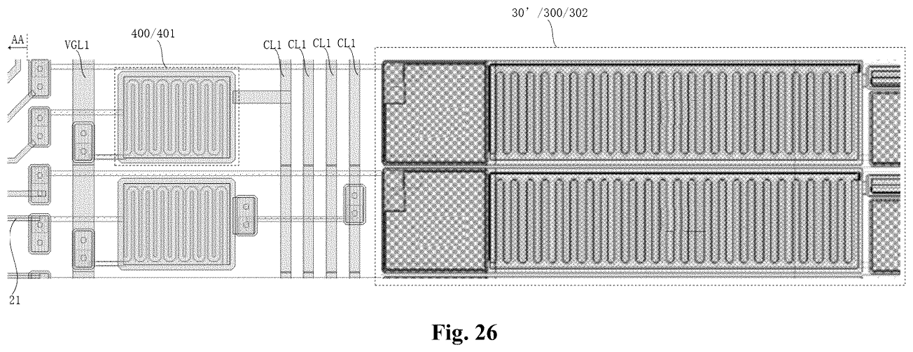

FIG. 26 is a partial schematic view of a display panel according to an embodiment of the present application.

In some possible embodiments, as shown in FIG. 26, the first non-enable signal wire VGL1 is located at a side of the first compensation module 401 close to the display region AA. Under a condition that the first compensation module group 40 is located between the second scan drive circuit 30′ and the display region AA, the first non-enable signal wire VGL1 is located between the first compensation module group 40 and the display region AA. The first non-enable signal wire VGL1 is located at a side of the first compensation module group 40 away from the second scan drive circuit 30′, so that the problem that the signal in the display region AA is affected by the peripheral signal may be reduced.

Further, as shown in FIG. 26, under a condition that the first control wire CL1 and the first non-enable signal wire VGL1 are located at two opposite sides of the first compensation module group 40, the first control wire CL1 is located at a side of the first compensation module group 40 close to the second scan drive circuit 30′.

It should be noted that FIG. 24 and FIG. 26 only show a part of the structures of the shift register 300.

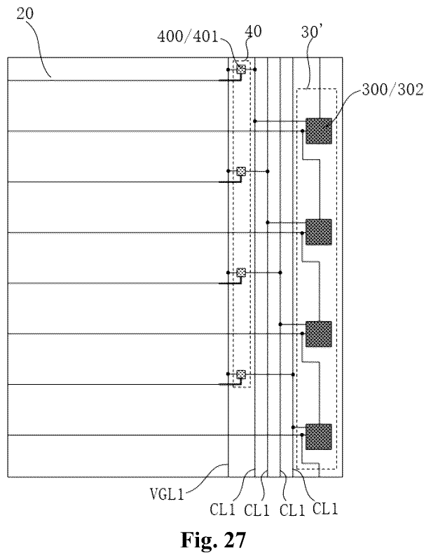

FIG. 27 is a partial schematic view of a display panel according to an embodiment of the present application.

Referring to FIG. 27, under a condition that the first control wire CL1 is located between the first compensation module group 40 and the second scan drive circuit 30′, the first control wire CL1 may be electrically connected to the enable output module 31 of the shift register 300 in the second scan drive circuit 30′. The first control wire CL1 may be electrically connected to the compensation module 400 in the first compensation module group 40 and also the shift register 300 in the second scan drive circuit 30′, which is conducive to reducing the number of the signal wires, reducing the dimension of the bezel of the display panel 01, and reducing the wiring difficulty.

Specifically, the first control wire CL1 may be electrically connected to the input terminal of the enable output module 31 of the shift register 300 in the second scan drive circuit 30′, so that the enable output module 31 of the shift register 300 in the second scan drive circuit 30′ can output the signal on the first control wire CL1 in parts of the periods.

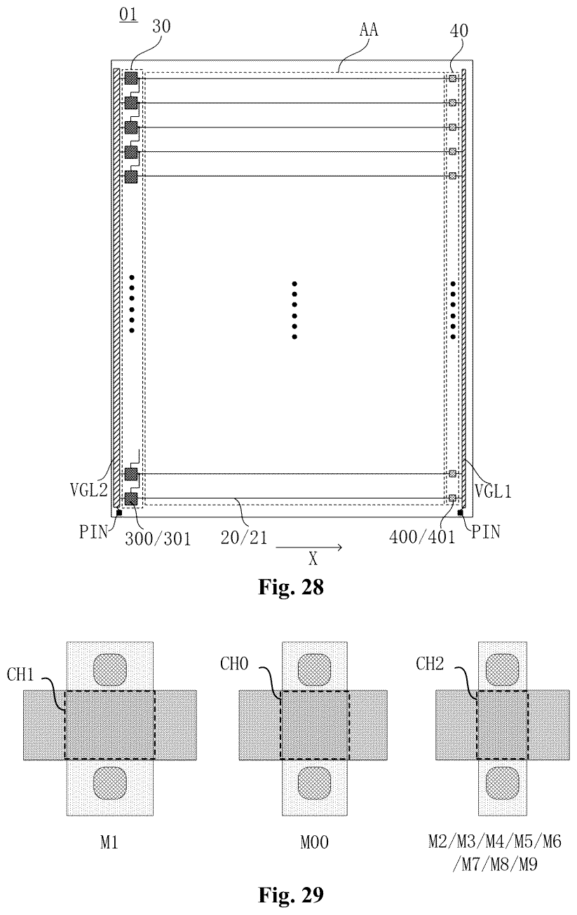

FIG. 28 is a schematic view of a display panel according to an embodiment of the present application.

In an embodiment of the present application, referring to FIG. 28, the display panel 01 further includes the second non-enable signal wire VGL2, the second non-enable signal wire VGL2 is connected between the shift register 300 and the non-enable signal terminal PIN in the first scan drive circuit 30, and the second non-enable signal wire VGL2 provides the non-enable signal to the first shift register 301. Further, the first non-enable signal wire VGL1 is connected between the compensation module 400 in the first compensation module group 40 and the non-enable signal terminal PIN, and the first non-enable signal wire VGL1 provides the non-enable signal to the first compensation module 401. FIG. 28 shows that the first non-enable signal wire VGL1 and the second non-enable signal wire VGL2 are electrically connected to different non-enable signal terminals PIN; in some situations, the first non-enable signal wire VGL1 and the second non-enable signal wire VGL2 are electrically connected to the same non-enable signal terminal pin.

Further, under a condition that the display panel 01 further includes the second scan drive circuit 30′, the non-enable signal wire from which the shift register 300 in the second scan drive circuit 30′ acquires the non-enable signal may be connected between the shift register 300 in the second scan drive circuit 30′ and the non-enable signal terminal PIN, that is, the second scan drive circuit 30′ and the first compensation module group 40 do not share the non-enable signal wire. In this embodiment, the first compensation module 401 and the shift register 300 may not share the non-enable signal wire from which the non-enable signal is acquired.

In this embodiment, as shown in FIG. 28, the width of the first non-enable signal wire VGL1 is less than the width of the second non-enable signal wire VGL2. Since the structure of the compensation module 400 is simpler than the structure of the shift register 300 in the scan drive circuit, the coupling capacitance in the compensation module 400 is less than the coupling capacitance of the shift register 300; the width of the first non-enable signal wire VGL1 is designed to be relatively small, so that under a condition that the requirement that the potential of the second end of the first scan wire 21 switches from the potential corresponding to the enable signal to the potential corresponding to the non-enable signal is satisfied, the width of the bezel is reduced.

FIG. 29 is a schematic structural view of different transistors in a display panel according to an embodiment of the present application.

In an embodiment of the present application, with reference to FIG. 14 and FIG. 29, the enable output module 31 of the shift register 300 in the first scan drive circuit 30 includes the first transistor M1, and the compensation module 400 in the first compensation module group 40 includes the compensation transistor M00. In FIG. 29, it is shown that the ratio of width-to-length (the ratio of the width along the row direction to the width along the column direction) of the channel CH1 of the first transistor M1 is the ratio of width-to-length of the first transistor M1, and the ratio of width-to-length (the ratio of the width along the row direction to the width along the column direction) of the channel CH0 of the compensation transistor M00 is the ratio of width-to-length of the compensation transistor M00. The ratio of width-to-length of the compensation transistor M00 in the first compensation module group 40 is less than the ratio of width-to-length of the first transistor M1 in the first scan drive circuit 30.

Since the load of the compensation transistor M00 is less than the load of the first transistor M1, the ratio of width-to-length of the compensation transistor M00 may be smaller, which is conducive to reducing the width of the bezel of the display panel, and reducing the design difficulty of the circuit in the bezel region of the display panel.

Furthermore, in FIG. 29, it is shown that the ratio of width-to-length of the channel CH2 (the ratio of the width along the row direction to the width along the column direction) is the ratio of width-to-length of the other transistors in the shift register 300 in the first scan drive circuit 30. The ratio of width-to-length of the compensation transistor M00 in the compensation module 400 in the first compensation module group 40 is greater than the ratio of width-to-length of the other transistors in the shift register 300 in the first scan drive circuit 30. For example, referring to FIG. 14 and FIG. 29, the ratio of width-to-length of the compensation transistor M00 in the compensation module 400 in the first compensation module group 40 is greater than the ratio of width-to-length of any one of the second transistor M2 to the ninth transistor M9 in the shift register 300 in the first scan drive circuit 30.

In the process in which the first scan wire 21 switches from transmitting the enable signal to transmitting the non-enable signal, the load of the compensation transistor M00 is larger than the loads of other transistors in the shift register 300 in the first scan drive circuit 30, and the ratio of the width-length of the compensation transistor M00 is designed to be greater, so that the speed at which the second end of the first scan wire 21 switches from the enable signal to the non-enable signal can be faster.

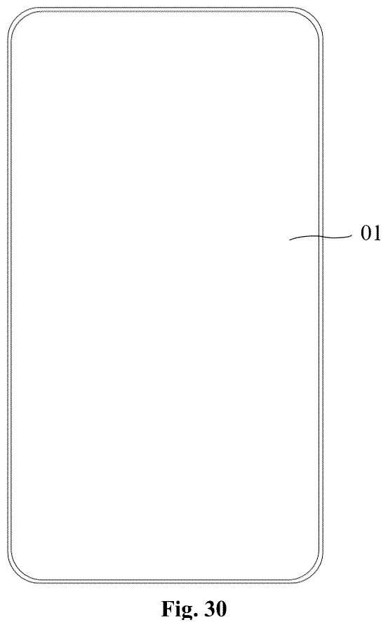

FIG. 30 is a schematic view of a display apparatus according to an embodiment of the present application.

Based on the same inventive concept, an embodiment of the present application further provides a display apparatus, and as shown in FIG. 30, the display apparatus includes the display panel 01. The display apparatus shown in FIG. 30 is only an example, and may be any electronic device having a display function, such as a mobile phone, a tablet computer, a notebook computer, an electronic paper book, or a television.

Technical solutions according to the embodiments of the present application can not only effectively solve the problem that the non-enable signals received by the first end and the second end of the first scan wire are different from each other due to the voltage drop and the problem that the non-enable signal received by the second end of the first scan wire is delayed, but also effectively reduce the problem of abnormal display by turning off in time the transistors electrically connected to different locations of the first scan wire.

What is claimed is:

1. A display panel comprising:
first scan wires;
a first scan drive circuit comprising a plurality of stages of shift registers in a cascaded connection, and the shift registers each comprising an enable output module; and an output terminal of one of the enable output modules of the shift registers in the first scan drive circuit being electrically connected to a first end of one of the first scan wires; and
a first compensation module group comprising a plurality of compensation modules; an input terminal of one of the compensation modules being electrically connected to a first non-enable signal wire, and an output terminal of one of the compensation modules being electrically connected to a second end of the one of the first scan wires; wherein
in a shift register of the shift registers in the first scan drive circuit and a compensation module of the compensation modules in the first compensation module group that is electrically connected to a same one of the first scan wires as the shift register, the compensation module is turned on in a switching period of the shift register, and the switching period is a period in which the enable output module of the shift register switches from outputting an enable signal to outputting a non-enable signal.

2. The display panel according to claim 1, wherein the display panel comprises a display region, and the first compensation module group and the first scan drive circuit are located at two opposite sides of the display region in a first direction; and the first direction is parallel to an extending direction of the first scan wires.

3. The display panel according to claim 1, further comprising first signal wires and first control wires, wherein
an input terminal of one of the enable output modules of the shift registers in the first scan drive circuit is electrically connected to one of the first signal wires, and the one of the enable output modules is configured to transmit a signal on the one of the first signal wires to the one of the first scan wires under a condition that the one of the enable output modules is turned on; and
one of the first control wires is electrically connected to a control end of one of the compensation modules in the first compensation module group, and the one of the first control wires is configured to transmit an active level signal for controlling the one of the compensation modules to be turned on and transmit a non-active level signal for controlling the one of the compensation modules to be turned off; and
in the one of the first control wires and the one of the first signal wires electrically connected respectively to the shift register in the first scan drive circuit and the compensation module in the first compensation module group that is electrically connected to the same first scan wire as the shift register, and during the switching period, a signal on the one of the first control wires is the active level signal before the signal on the one of the first signal wires changes to the non-enable signal.

4. The display panel according to claim 3, wherein in the one of the first control wires and the one of the first signal wires electrically connected respectively to the shift register in the first scan drive circuit and the compensation module in the first compensation module group that is electrically connected to the same first scan wire as the shift register, and during the switching period, a start moment at which the signal on the one of the first control wires switches from the non-active level signal to the active level signal is the same as a start moment at which the signal on the one of the first signal wires switches from the enable signal to the non-enable signal; or,
in the one of the first control wires and the one of the first signal wires electrically connected respectively to the shift register in the first scan drive circuit and the compensation module in the first compensation module group that is electrically connected to the same first scan wire as the shift register, before the switching period starts, the signal on the one of the first control wires starts switching from the non-active level signal to the active level signal.

5. The display panel according to claim 3, wherein at least two of the compensation modules of the first compensation module group are electrically connected to different ones of the first control wires.

6. The display panel according to claim 5, wherein a number of the first signal wires electrically connected to the first scan drive circuit is equal to a number of the first control wires electrically connected to the first compensation module group.

7. The display panel according to claim 3, wherein the first control wires and the first non-enable signal wires electrically connected to the first compensation module group are located at two sides of the first compensation module.

8. The display panel according to claim 3, further comprising a second scan drive circuit comprising a plurality of stages of shift registers in a cascaded connection, wherein
the display panel comprises a display region, the second scan drive circuit and the first compensation module group are located at a same side of the display region, and the first compensation module group and the first scan drive circuit are located at two opposite sides of the display region respectively.

9. The display panel according to claim 8, wherein the first compensation module group is located at a side of the second scan drive circuit close to the display region.

10. The display panel according to claim 8, wherein the first control wires are located at a side of the first compensation module group away from the second scan drive circuit.

11. The display panel according to claim 10, wherein the first non-enable signal wires are located between the first compensation module group and the second scan drive circuit and are electrically connected to the shift registers in the second scan drive circuit.

12. The display panel according to claim 8, wherein the first non-enable signal wires are located at a side of the first compensation module group close to the display region.

13. The display panel according to claim 12, wherein the first control wires are located at a side of the first compensation module group close to the second scan drive circuit, and are electrically connected to enable output modules of the shift registers in the second scan drive circuit.

14. The display panel according to claim 8, wherein
the one of the first scan wires comprises a first sub-scan wire and a second sub-scan wire;
the display panel further comprises a second compensation module group, the second scan drive circuit comprises a plurality of stages of shift registers in a cascaded connection, and the second compensation module group comprises a plurality of compensation modules;
the first scan drive circuit and the second compensation module group are located at a same side of the display region, the second scan drive circuit and the first compensation module group are located at a same side of the display region, and the first scan drive circuit and the second scan drive circuit are located at the two opposite sides of the display region respectively; and
the output terminal of the enable output module in the first scan drive circuit is electrically connected to a first end of the first sub-scan wire, and the output terminal of the compensation module in the first compensation module group is electrically connected to a second end of the first sub-scan wire; an output terminal of one of enable output modules in the second scan drive circuit is electrically connected to a first end of the second sub-scan wire, and the output terminal of the compensation module in the first compensation module group is electrically connected to a second end of the second sub-scan wire.

15. The display panel according to claim 1, wherein the display panel further comprises a second non-enable signal wire connected between the shift register in the first scan drive circuit and a non-enable signal terminal, and the first non-enable signal wire is connected between the compensation module in the first compensation module group and the non-enable signal terminal; and
a width of the first non-enable signal wire is less than a width of the second non-enable signal wire.

16. The display panel according to claim 1, wherein the enable output module of the shift register in the first scan drive circuit comprises a first transistor; the compensation module in the first compensation module group comprises a compensation transistor; a ratio of width-to-length of the compensation transistor in the first compensation module group is less than a ratio of width-to-length of the first transistor in the first scan drive circuit and greater than a ratio of width-to-length of other transistors in the shift register in the first scan drive circuit.

17. The display panel according to claim 1, wherein the display panel further comprises a pixel circuit and a data wire, the pixel circuit comprises a drive transistor and a data voltage writing module, an input terminal of the data voltage writing module is electrically connected to the data wire, and the data voltage writing module is configured to transmit a data voltage transmitted on the data wire to the drive transistor; and
the one of the first scan wires is electrically connected to a control end of the data voltage writing module.

18. The display panel according to claim 17, wherein the data voltage writing module comprises an N-channel transistor, and the first scan wire is electrically connected to a gate of the N-channel transistor in the data voltage writing module.

19. The display panel according to claim 18, wherein the compensation module in the first compensation module group comprises a compensation transistor, the compensation transistor is the N-channel transistor, and a gate of the compensation transistor is electrically connected to the first control wire; and
in the one of the first control wires and the one of the first signal wires electrically connected respectively to the shift register in the first scan drive circuit and the compensation module in the first compensation module group that is electrically connected to the same first scan wire as the shift register, and during the switching period, a rising edge of a signal transmitted by the first control wire and a falling edge of a signal transmitted by the first signal wire at least partially overlap.

20. A display apparatus comprising a display panel comprising: first scan wires; a first scan drive circuit comprising a plurality of stages of shift registers in a cascaded connection, and the shift registers each comprising an enable output module; and an output terminal of one of the enable output modules of the shift registers in the first scan drive circuit being electrically connected to a first end of one of the first scan wires; and a first compensation module group comprising a plurality of compensation modules; an input terminal of one of the compensation modules being electrically connected to a first non-enable signal wire, and an output terminal of one of the compensation modules being electrically connected to a second end of the one of the first scan wires; wherein in a shift register of the shift registers in the first scan drive circuit and a compensation module of the compensation modules in the first compensation module group that is electrically connected to a same one of the first scan wires as the shift register, the compensation module is turned on in a switching period of the shift register, and the switching period is a period in which the enable output module of the shift register switches from outputting an enable signal to outputting a non-enable signal.
